(19) United States
(12) Patent Application Publication
(10) Pub. No.: US 2024/0162370 A1
(43) Pub. Date: May 16, 2024

(54) SEMICONDUCTOR LIGHT-EMITTING DEVICE

(71) Applicant: ROHM CO., LTD., Kyoto-shi (JP)

(72) Inventor: Yohei ITO, Kyoto-shi (JP)

(21) Appl. No.: 18/404,200

(22) Filed: Jan. 4, 2024

Related U.S. Application Data
(63) Continuation of application No. PCT/JP2022/021563, filed on May 26, 2022.

(30) Foreign Application Priority Data
Jul. 16, 2021 (JP) 2021-117769

(51) Int. Cl. H01L 33/02; H01L 33/38

(52) U.S. Cl. CPC H01L 33/02; H01L 33/38

(57) ABSTRACT

A semiconductor light-emitting device includes a substrate, a semiconductor layer that is laminated on the substrate and that generates light, and a metal layer that is interposed between the substrate and the semiconductor layer and that has a laminated structure including Au films each of which is made of an Au-based metal, wherein a ratio of a total thickness of the Au films with respect to a thickness of the semiconductor layer is not less than 0.03 and not more than 0.25.

### CROSS REFERENCE TO RELATED APPLICATIONS

The present application is a bypass continuation of International Patent Application No. PCT/JP2022/021563, filed on May 26, 2022, which claims priority to Japanese Patent Application No. 2021-117769 filed in the Japan Patent Office on Jul. 16, 2021, the entire disclosure of which is incorporated herein by reference.

### BACKGROUND

### 1. Field of the Disclosure

The present disclosure relates to a semiconductor light-emitting device.

### 2. Description of the Related Art

United States patent application publication No. 2005/0110037 discloses a semiconductor light-emitting element that includes a silicon substrate, a semiconductor layer that generates light, and a metal layer interposed between the silicon substrate and the semiconductor layer.

### BRIEF DESCRIPTION OF THE DRAWINGS

FIG. 1 is a plan view of a semiconductor light-emitting device according to a first embodiment.

FIG. 2 is a cross-sectional view taken along line II-II shown in FIG. 1.

FIG. 3 is an enlarged cross-sectional view of a metal layer shown in FIG. 2.

FIG. 4 is an enlarged cross-sectional view of a pad electrode shown in FIG. 2.

FIG. 5 is a plan view showing a first package.

FIG. 6 is a cross-sectional view taken along line VI-VI shown in FIG. 5.

FIG. 7A is a cross-sectional view showing an example of a method for manufacturing the semiconductor light-emitting device shown in FIG. 1.

FIG. 7B is a cross-sectional view showing a step subsequent to the step shown in FIG. 7A.

FIG. 7C is a cross-sectional view showing a step subsequent to the step shown in FIG. 7B.

FIG. 7D is a cross-sectional view showing a step subsequent to the step shown in FIG. 7C.

FIG. 7E is a cross-sectional view showing a step subsequent to the step shown in FIG. 7D.

FIG. 7F is a cross-sectional view showing a step subsequent to the step shown in FIG. 7E.

FIG. 7G is a cross-sectional view showing a step subsequent to the step shown in FIG. 7F.

FIG. 7H is a cross-sectional view showing a step subsequent to the step shown in FIG. 7G.

FIG. 7I is a cross-sectional view showing a step subsequent to the step shown in FIG. 7H.

FIG. 7J is a cross-sectional view showing a step subsequent to the step shown in FIG. 7I.

FIG. 7K is a cross-sectional view showing a step subsequent to the step shown in FIG. 7J.

FIG. 8A is a cross-sectional view showing an example of a method for manufacturing the first package shown in FIG. 5.

FIG. 8B is a cross-sectional view showing a step subsequent to the step shown in FIG. 8A.

FIG. 8C is a cross-sectional view showing a step subsequent to the step shown in FIG. 8B.

FIG. 8D is a cross-sectional view showing a step subsequent to the step shown in FIG. 8C.

FIG. 9 is a cross-sectional view showing a semiconductor light-emitting device according to a first reference mode.

FIG. 10 is a cross-sectional view showing a mode taken when a peel test of a bonding wire is performed with respect to the semiconductor light-emitting device shown in FIG. 9.

FIG. 11 is a cross-sectional view showing a semiconductor light-emitting device according to a second reference mode.

FIG. 12 is a cross-sectional view showing a mode taken when a peel test of a bonding wire is performed with respect to the semiconductor light-emitting device shown in FIG. 11.

FIG. 13 is a cross-sectional view showing a mode taken when a peel test of a bonding wire is performed with respect to the semiconductor light-emitting device shown in FIG. 1.

FIG. 14 is a cross-sectional view of a semiconductor light-emitting device according to a second embodiment.

FIG. 15 is a plan view showing a second package.

FIG. 16 is a cross-sectional view taken along line XVI-XVI shown in FIG. 15.

FIG. 17A is a cross-sectional view showing an example of a method for manufacturing a second package shown in FIG. 15.

FIG. 17B is a cross-sectional view showing a step subsequent to the step shown in FIG. 17A.

FIG. 17C is a cross-sectional view showing a step subsequent to the step shown in FIG. 17B.

FIG. 17D is a cross-sectional view showing a step subsequent to the step shown in FIG. 17C.

FIG. 17E is a cross-sectional view showing a step subsequent to the step shown in FIG. 17D.

### DETAILED DESCRIPTION OF THE PREFERRED EMBODIMENTS

An embodiment will be hereinafter described in detail. The accompanying drawings are schematic views, and are not necessarily shown strictly, and do not necessarily coincide with each other in scale, etc. The same reference sign is assigned to a constituent that corresponds to each constituent in the accompanying drawings, and a duplicated description of this constituent is omitted or simplified. A description of a constituent, before omission or simplification, is applied to a corresponding constituent a description of which is omitted or simplified.

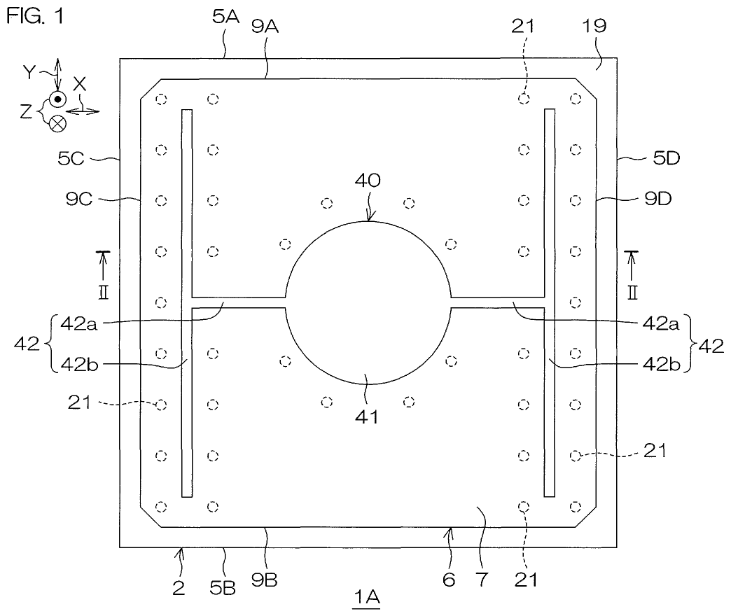

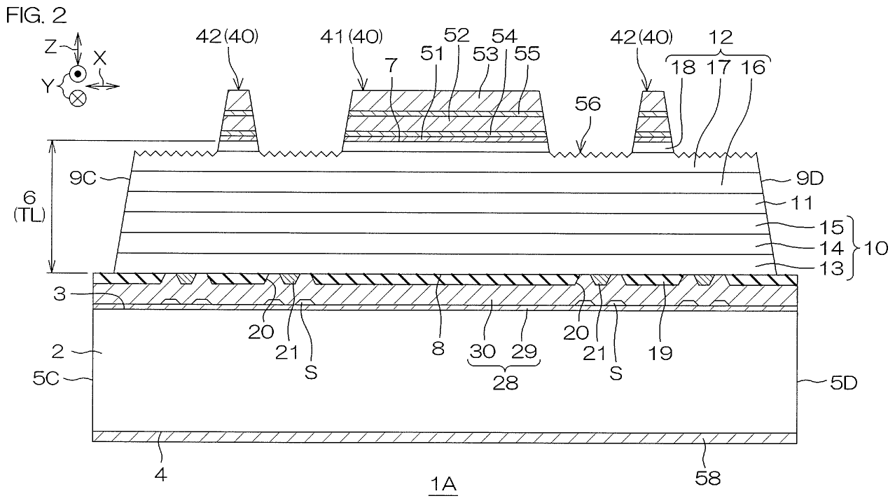

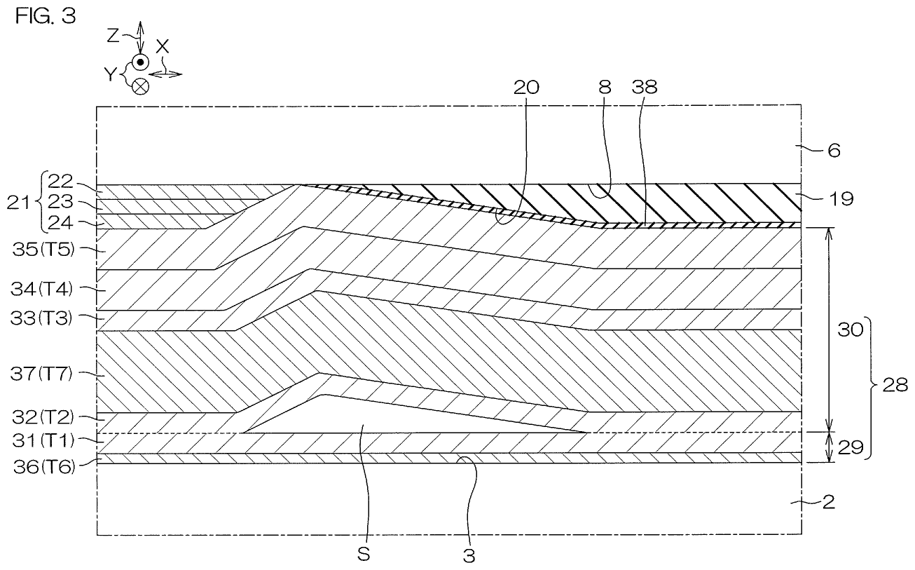

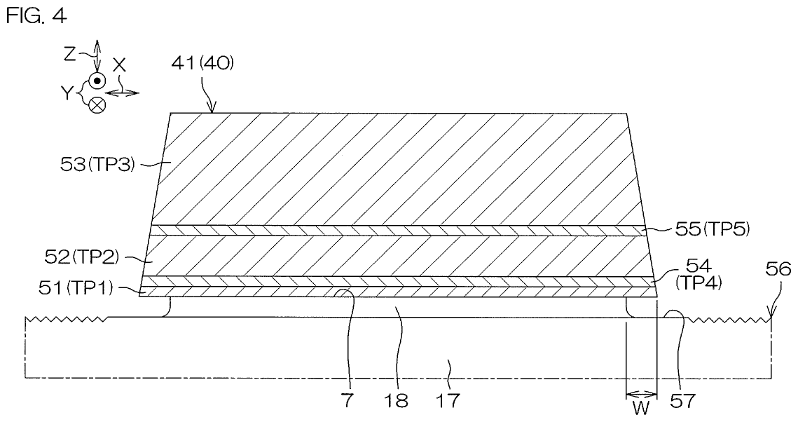

FIG. 1 is a plan view of a semiconductor light-emitting device 1A according to a first embodiment. FIG. 2 is a cross-sectional view taken along line II-II of FIG. 1. FIG. 3 is an enlarged cross-sectional view of a metal layer 28 shown in FIG. 2. FIG. 4 is an enlarged cross-sectional view of a first pad electrode 40 shown in FIG. 2.

Referring to FIG. 1 and FIG. 2, the semiconductor light-emitting device 1A includes a substrate 2 (semiconductor substrate) formed in a rectangular parallelepiped shape. The substrate 2 may include at least one among a silicon substrate, a silicon carbide substrate, a germanium substrate, a compound semiconductor substrate, and a nitride semiconductor substrate. The substrate 2 is made of a silicon substrate in this embodiment. The substrate 2 includes a first main surface 3 on one side, a second main surface 4 on the other side, and first to fourth side surfaces 5A to 5D connecting the first main surface 3 and the second main surface 4.

The first and second main surfaces 3 and 4 are each formed in a quadrangular shape in a plan view seen from a normal direction Z along a thickness direction of the substrate 2 (hereinafter, referred to simply as a “plan view”). The first side surface 5A and the second side surface 5B extend in a first direction X along the first main surface 3, and face each other (face opposite to each other) in a second direction Y intersecting (specifically, orthogonal to) the first direction X. The third side surface 5C and the fourth side surface 5D extend in the second direction Y, and face each other in the first direction X. The length of a side of the substrate 2 (each of the lengths of the first to fourth side surfaces 5A to 5D) may be not less than 0.2 mm and not more than 1 mm. The thickness of the substrate 2 may be not less than 50 μm and not more than 400 μm.

The semiconductor light-emitting device 1A includes a semiconductor layer 6 laminated on the substrate 2. The semiconductor layer 6 is an epitaxial layer (compound semiconductor layer) made of a compound semiconductor. The semiconductor layer 6 has a first end surface 7 on one side (i.e., side opposite to the substrate 2), a second end surface 8 on the other side (i.e., on the substrate 2 side), and first to fourth peripheral walls 9A to 9D connecting the first end surface 7 and the second end surface 8.

The first end surface 7 is formed in a quadrangular shape in the plan view. The second end surface 8 is formed in a quadrangular shape having an area larger than the first end surface 7 in the plan view. The first peripheral wall 9A and the second peripheral wall 9B extend in the first direction X, and face each other (face opposite to each other) in the second direction Y. The third peripheral wall 9C and the fourth peripheral wall 9D extend in the second direction Y, and face each other in the first direction X.

The first to fourth peripheral walls 9A to 9D are formed at a distance inwardly from the first to fourth side surfaces 5A to 5D in the plan view. The first to fourth peripheral walls 9A to 9D diagonally downwardly incline from the first end surface 7 toward the second end surface 8. Hence, the semiconductor layer 6 is formed in a mesa form having a truncated cone or pyramid shape (in this embodiment, truncated four-sided pyramid shape). In other words, the semiconductor layer 6 is formed in a trapezoidal shape in a cross-sectional view.

As a matter of course, the first end surface 7 and the second end surface 8 may be each formed in a circular shape in the plan view. In other words, the semiconductor layer 6 may be formed in a truncated cone shape. The semiconductor layer 6 has a predetermined layer thickness TL. The layer thickness TL may be not less than 4 μm and not more than 10 μm. Preferably, the layer thickness TL is not less than 6 μm and not more than 9 μm.

The semiconductor layer 6 is configured to generate light. The light generated by the semiconductor layer 6 may be green light (550 nm to 580 nm), yellow light (580 nm to 600 nm), orange light (600 nm to 615 nm), or red light (615 nm to 770 nm).

The semiconductor layer 6 has a double hetero laminated structure including a p-type (first conductivity type) first semiconductor layer 10, an light-emitting layer 11, and an n-type (second conductivity type) second semiconductor layer 12 that are laminated in that order from a side of the substrate 2. The light-emitting layer 11 generates light by recombining a hole from the first semiconductor layer 10 and an electron from the second semiconductor layer 12.

The first semiconductor layer 10 forms part of the second end surface 8 of the semiconductor layer 6 and part of the first to fourth peripheral walls 9A to 9D. The first semiconductor layer 10 includes a p-type first contact layer 13, a p-type first window layer 14, and a p-type first cladding layer 15 that are laminated in that order from the side of the substrate 2. The first contact layer 13 may include a GaP layer.

The first contact layer 13 may include carbon as a p-type impurity. The first contact layer 13 may have a thickness of not less than 0.1 μm and not more than 2.5 μm. The first contact layer 13 is a low resistance layer having a p-type impurity concentration higher than the first window layer 14 and than the first cladding layer 15.

The first window layer 14 may include a GaP layer. The first window layer 14 may include magnesium as a p-type impurity. The first window layer 14 may have a thickness of not less than 0.1 μm and not more than 2.5 μm. The first cladding layer 15 may include an AlInP layer. The first cladding layer 15 may include magnesium as a p-type impurity. The first cladding layer 15 may have a thickness of not less than 0.1 μm and not more than 2.5 μm.

The light-emitting layer 11 is laminated on the first semiconductor layer 10, and forms part of the first to fourth peripheral walls 9A to 9D of the semiconductor layer 6. The light-emitting layer 11 has a multiple-quantum well structure in which a plurality of barrier layers and a plurality of quantum well layers are alternately laminated. The number of laminated layers of both the barrier layer and the quantum well layer may be not less than 10 and not more than 50. The barrier layers each include an AlInGaP layer. The barrier layers may each have a thickness of not less than 1 nm and not more than 10 nm.

If the light-emitting layer 11 is a layer that generates red light, the quantum well layers each include an InGaP layer. In this case, the wavelength of the light generated by the light-emitting layer 11 is adjusted by the In composition ratio of the quantum well layer. When the In composition ratio becomes large, the wavelength of the light becomes large.

If the light-emitting layer 11 is a layer that generates green light, yellow light, or orange light, the quantum well layers each include an AlInGaP layer. In this case, the wavelength of the light generated by the light-emitting layer 11 is adjusted by the Al composition ratio of the quantum well layer. When the Al composition ratio becomes large, the wavelength of the light becomes small. The quantum well layers may each have a thickness of not less than 1 nm and not more than 10 nm. Preferably, the thickness of the quantum well layer is less than the thickness of the barrier layer.

The second semiconductor layer 12 is laminated on the light-emitting layer 11, and forms part of the first end surface 7 of the semiconductor layer 6 and part of the first to fourth peripheral walls 9A to 9D. The second semiconductor layer 12 includes an n-type second cladding layer 16, an n-type second window layer 17, and an n-type second contact layer 18 that are laminated in that order from a side of the light-emitting layer 11. The second cladding layer 16 may include an AlInP layer. The second cladding layer 16 may include silicon as an n-type impurity. The second cladding layer 16 may have a thickness of not less than 0.1 μm and not more than 2.5 μm.

The second window layer 17 may include an AlInGaP layer. The second window layer 17 may include silicon as an n-type impurity. The second window layer 17 may have a thickness of not less than 2 μm and not more than 5 μm. The second contact layer 18 may include a GaAs layer.

The second contact layer 18 may include silicon as an n-type impurity. The second contact layer 18 may have a thickness of not less than 0.1 μm and not more than 2.5 μm. The second contact layer 18 is a low resistance layer having an n-type impurity concentration higher than the second window layer 17 and than the second cladding layer 16.

The semiconductor light-emitting device 1A includes an insulating film 19 interposed between the substrate 2 and the semiconductor layer 6 so as to cover the semiconductor layer 6. The insulating film 19 includes at least one of a silicon oxide film and a silicon nitride film. The insulating film 19 may be an oxide film. In this embodiment, the insulating film 19 has a single layer structure made of a silicon nitride film. The insulating film 19 covers the whole area of the second end surface 8 of the semiconductor layer 6, and projects more outwardly than the first to fourth peripheral walls 9A to 9D of the semiconductor layer 6. The thickness of the insulating film 19 may be not less than 0.1 μm and not more than 0.5 μm.

The insulating film 19 includes a plurality of contact openings 20 that expose the second end surface 8 (first contact layer 13) of the semiconductor layer 6. In this embodiment, the contact openings 20 are each formed in a tapered shape whose opening width becomes smaller in proportion to an advance toward the semiconductor layer 6 in a cross-sectional view. The contact openings 20 are each formed in a circular shape in the plan view. The arrangement and the size of the contact openings 20 are arbitrary.

The semiconductor light-emitting device 1A includes a plurality of contact electrodes 21 arranged in the contact openings 20, respectively. The contact electrodes 21 are electrically connected to the second end surface 8 (first contact layer 13) of the semiconductor layer 6. The contact electrodes 21 are each formed in a tapered shape that becomes gradually narrower toward the substrate 2 side in a cross-sectional view.

The contact electrode 21 may be formed at a distance inwardly from a wall surface of the contact opening 20 so as to expose a part of the semiconductor layer 6. The contact electrode 21 may cover a part of the wall surface of the contact opening 20. The contact electrode 21 may cover the whole area of a part, which is exposed from the contact opening 20, of the semiconductor layer 6.

In this embodiment, the contact electrode 21 has a laminated structure including a plurality of conductor films. Specifically, the contact electrode 21 includes a first conductor film 22, a second conductor film 23, and a third conductor film 24 that are laminated in that order from a side of the second end surface 8. The first conductor film 22 may include an Au-based metal. Pure Au (non-alloy Au) and an Au alloy are exemplified as the Au-based metal (hereinafter, the same applies). In this embodiment, the first conductor film 22 includes an AuBe alloy film that includes AuBe as an example of the Au alloy, and covers the second end surface 8.

The second conductor film 23 may include an Ni-based metal. Pure Ni (non-alloy Ni) and an Ni alloy are exemplified as the Ni-based metal (hereinafter, the same applies). In this embodiment, the second conductor film 23 includes a pure Ni film, and covers the first conductor film 22. The third conductor film 24 may include an Au-based metal. In this embodiment, the third conductor film 24 includes a pure Au film, and covers the second conductor film 23.

Preferably, the contact electrode 21 has a thickness equal to or less than the thickness of the insulating film 19. The thickness of the contact electrode 21 may be not less than 0.15 μm and not more than 0.5 μm. The thickness of the first conductor film 22 may be not less than 0.1 μm and not more than 0.3 μm. Preferably, the thickness of the second conductor film 23 is less than the thickness of the first conductor film 22. The thickness of the second conductor film 23 may be not less than 5 nm and not more than 20 nm. Preferably, the thickness of the third conductor film 24 is more than the thickness of the second conductor film 23, and is less than the thickness of the first conductor film 22. The thickness of the third conductor film 24 may be not less than 0.05 μm and not more than 0.2 μm.

The semiconductor light-emitting device 1A includes a metal layer 28 interposed between the substrate 2 and the semiconductor layer 6. Specifically, the metal layer 28 is interposed between the substrate 2 and the insulating film 19 so as to be electrically connected to the contact electrodes 21. The metal layer 28 is electrically connected to the substrate 2 and to the semiconductor layer 6, and joins the substrate 2 and the semiconductor layer 6.

The metal layer 28 includes a first metal layer 29 on the substrate 2 side and a second metal layer 30 on the semiconductor layer 6 side. The first metal layer 29 includes a first Au film 31. The first Au film 31 is a first Au junction film including an Au-based metal. In this embodiment, the first Au film 31 includes a pure Au film, and covers the whole area of the first main surface 3 of the substrate 2.

The second metal layer 30 is laminated on the first metal layer 29. The second metal layer 30 includes a second Au film 32, a third Au film 33, a fourth Au film 34, and a fifth Au film 35 that are laminated in that order from a side of the first metal layer 29.

The second Au film 32 is a second Au junction film including an Au-based metal. In this embodiment, the second Au film 32 includes a pure Au film, and covers the whole area of the first Au film 31. The second Au film 32 is a second Au junction film pressed and bonded to the first Au film 31. The second Au film 32 forms a void space S between the second Au film 32 and the first Au film 31 in a part, which faces a region between an inner wall of the contact opening 20 and the contact electrode 21, of the second Au film 32. As a matter of course, the whole area of the second Au film 32 may be closely bonded to the first Au film 31 without forming the void space S. A plurality of fine holes may be formed at a distance from each other in a boundary portion between the first Au film 31 and the second Au film 32 along this boundary portion.

The third Au film 33 is a first Au light reflecting film including an Au-based metal. In this embodiment, the third Au film 33 includes a pure Au film, and covers the whole area of the second Au film 32. The fourth Au film 34 is an Au alloy film including an Au alloy. In this embodiment, the fourth Au film 34 is an AuBe alloy film including AuBe as an example of the Au alloy. The fourth Au film 34 covers the whole area of the third Au film 33.

The fifth Au film 35 is a second Au light reflecting film including an Au-based metal. In this embodiment, the fifth Au film 35 includes a pure Au film, and covers the whole area of the fourth Au film 34. The fifth Au film 35 covers the insulating film 19 so as to enter the contact openings 20. The fifth Au film 35 covers the contact electrodes 21 in the contact openings 20. Hence, the fifth Au film 35 is electrically connected to the contact electrodes 21.

The fourth Au film 34 is provided as an element supply source that supplies Be to the third Au film 33 and to the fifth Au film 35 by diffusion. Therefore, the third Au film 33 may include Be that is diffused from the fourth Au film 34. Also, the fifth Au film 35 may include Be that is diffused from the fourth Au film 34.

The first Au film 31 has a first thickness T1. The first thickness T1 may be not less than 0.075 μm and not more than 0.125 μm. Preferably, the first thickness T1 is equal to or more than 0.1 μm.

The second Au film 32 has a second thickness T2. The second thickness T2 may be not less than 0.075 μm and not more than 0.125 μm. Preferably, the second thickness T2 is equal to or more than 0.1 μm.

The third Au film 33 has a third thickness T3. Preferably, the third thickness T3 is less than the first thickness T1. Preferably, the third thickness T3 is less than the second thickness T2. The third thickness T3 may be not less than 0.01 μm and not more than 0.1 μm. Preferably, the third thickness T3 is equal to or more than 0.05 μm.

The fourth Au film 34 has a fourth thickness T4. Preferably, the fourth thickness T4 is equal to or more than the third thickness T3. The fourth thickness T4 may be not less than 0.05 μm and not more than 0.15 μm. Preferably, the fourth thickness T4 is equal to or more than 0.1 μm.

The fifth Au film 35 has a fifth thickness T5. Preferably, the fifth thickness T5 is equal to or more than the third thickness T3. The fifth thickness T5 may be not less than 0.05 μm and not more than 0.15 μm. Preferably, the fifth thickness T5 is equal to or more than 0.1 μm.

Preferably, the total thickness (=T3+T4+T5) of the third to fifth thicknesses T3 to T5 is equal to or more than the total thickness (=T1+T2) of the first and second thicknesses T1 and T2. Particularly preferably, the total thickness of the third to fifth thicknesses T3 to T5 is more than the total thickness of the first and second thicknesses T1 and T2. Preferably, the ratio T4/T5 of the fourth thickness T4 to the fifth thickness T5 is not less than 0.2 and not more than 1.5.

Particularly preferably, the ratio T4/T5 is equal to or less than 1. A total thickness TA (=T1+T2+T3+T4+T5) of the first to fifth Au films 31 to 35 is less than the layer thickness TL of the semiconductor layer 6. Preferably, the thickness ratio TA/TL of the total thickness TA to the layer thickness TL is not less than 0.03 and not more than 0.25. Particularly preferably, the thickness ratio TA/TL is not less than 0.04 and not more than 0.08.

The first metal layer 29 includes a first Ti film 36 interposed between the substrate 2 and the first Au film 31. The first Ti film 36 is a first barrier film including a Ti-based metal. Pure Ti (non-alloy Ti) and a Ti alloy are exemplified as the Ti-based metal (hereinafter, the same applies). In this embodiment, the first Ti film 36 includes a pure Ti film, and is interposed in the whole area between the substrate 2 (first main surface 3) and the first Au film 31. The first Ti film 36 suppresses the diffusion of Au into the substrate 2.

The second metal layer 30 includes a second Ti film 37 interposed between the second Au film 32 and the third Au film 33. The second Ti film 37 is a second barrier film including a Ti-based metal. In this embodiment, the second Ti film 37 includes a pure Ti film, and is interposed in the whole area between the second Au film 32 and the third Au film 33. The second Ti film 37 suppresses the diffusion of Be included in the fourth Au film 34 into the first Au film 31 and into the second Au film 32.

The first Ti film 36 has a sixth thickness T6. Preferably, the sixth thickness T6 is less than the first thickness T1 of the first Au film 31 (T6<T1). Preferably, the sixth thickness T6 is less than the second thickness T2 of the second Au film 32 (T6<T2). The sixth thickness T6 may be not less than 0.01 μm and not more than 0.1 μm.

The second Ti film 37 has a seventh thickness T7. Preferably, the seventh thickness T7 is larger than any one of the first to fifth thicknesses T1 to T5. Preferably, the seventh thickness T7 is larger than at least either one of the first thickness T1 and the second thickness T2. In this embodiment, the seventh thickness T7 is larger than the total thickness of the first and second thicknesses T1 and T2. Also, the seventh thickness T7 is larger than each of the first to fifth thicknesses T1 to T5 (T1 to T5<T7). The seventh thickness T7 may have a thickness of not less than 0.1 μm and not more than 0.5 μm.

The semiconductor light-emitting device 1A includes a dissimilar insulating film 38 that is interposed between the insulating film 19 and the metal layer 28 and that includes an insulator differing from that of the insulating film 19. The dissimilar insulating film 38 includes BeO (beryllium oxide) in which Be diffused from the fourth Au film 34 is combined with O (oxygen) of the insulating film 19. The dissimilar insulating film 38 is interposed between the insulating film 19 and the second metal layer 30 (fifth Au film 35), and is not interposed between the contact electrode 21 and the second metal layer 30. The dissimilar insulating film 38 increases the adhesive force of the second metal layer 30 (fifth Au film 35) with respect to the insulating film 19.

The semiconductor light-emitting device 1A includes a first pad electrode 40 laminated on the semiconductor layer 6. The first pad electrode 40 is electrically connected to the first end surface 7 (second semiconductor layer 12). The first pad electrode 40 is arranged on the semiconductor layer 6 at a distance inwardly from the first to fourth peripheral walls 9A to 9D.

The first pad electrode 40 has a main body portion 41 and at least one arm portion 42 (in this embodiment, a plurality of arm portions 42). In this embodiment, the main body portion 41 is formed in a circular shape in the plan view. The main body portion 41 may be formed in a polygonal shape (for example, quadrangular shape) in the plan view. The diameter (maximum width) of the main body portion 41 may be not less than 80 μm and not more than 120 μm in the plan view. Preferably, the diameter (maximum width) of the main body portion 41 is equal to or more than 100 μm in the plan view.

The arm portions 42 are linearly led out from the main body portion 41 toward the peripheral edge portion of the semiconductor layer 6. In this embodiment, the arm portions 42 are each led out from the main body portion 41 in the shape of the letter T in the plan view. Specifically, the arm portions 42 each include a first band portion 42a and a second band portion 42b. The first band portion 42a linearly extends from the main body portion 41 in one direction (in this embodiment, the first direction X). The second band portion 42b linearly extends in an orthogonal direction (in this embodiment, the second direction Y) perpendicular to the one direction (the first direction X) so as to be continuous with a tip end portion of the first band portion 42a.

Preferably, the main body portion 41 is arranged in a region that does not coincide with the contact electrodes 21 (contact openings 20) in the plan view. Also, preferably, the arm portions 42 (first band portion 42a and second band portion 42b) are led out to a region that does not coincide with the contact electrodes 21 (contact openings 20) in the plan view.

In other words, preferably, the contact electrodes 21 are formed at a distance from the main body portion 41 and from the arm portions 42 in the plan view. In this case, preferably, the contact electrodes 21 are arranged along the main body portion 41 and along the arm portions 42 in the plan view.

The first pad electrode 40 includes a first Au pad film 51, a second Au pad film 52, and a third Au pad film 53 that are laminated in that order from a side of the semiconductor layer 6. The first Au pad film 51 is an Au alloy film including an Au alloy. In this embodiment, the first Au pad film 51 is made of an AuGe alloy film including AuGe as an example of the Au alloy, and covers the semiconductor layer 6 (second contact layer 18).

The second Au pad film 52 includes an Au-based metal. In this embodiment, the second Au pad film 52 includes a pure Au film, and covers the first Au pad film 51. The third Au pad film 53 includes an Au-based metal. In this embodiment, the third Au pad film 53 includes a pure Au film, and covers the second Au pad film 52.

The first Au pad film 51 has a first pad thickness TP1. The first pad thickness TP1 may be not less than 0.01 μm and not more than 0.1 μm. Preferably, the first pad thickness TP1 is not less than 0.025 μm and not more than 0.075 μm.

The second Au pad film 52 has a second pad thickness TP2. Preferably, the second pad thickness TP2 exceeds the first pad thickness TP1 (TP1<TP2). The second pad thickness TP2 may be not less than 0.1 μm and not more than 1 μm. Preferably, the second pad thickness TP2 is not less than 0.3 μm and not more than 0.5 μm.

The third Au pad film 53 has a third pad thickness TP3. Preferably, the third Au pad film 53 exceeds the first pad thickness TP1 (TP1<TP3). Particularly preferably, the third pad thickness TP3 exceeds the second pad thickness TP2 (TP2<TP3). The third pad thickness TP3 may be not less than 1 μm and not more than 3 μm. Preferably, the third pad thickness TP3 is not less than 1.5 μm and not more than 2.5 μm. Preferably, a total thickness TP (=TP1+TP2+TP3) of the first to third Au pad films 51 to 53 exceeds the total thickness TA of the first to fifth Au films 31 to 35 (TA<TP).

The first pad electrode 40 includes an Ni pad film 54 interposed between the first Au pad film 51 and the second Au pad film 52. The Ni pad film 54 includes an Ni-based metal. In this embodiment, the Ni pad film 54 includes a pure Ni film, and is interposed in the whole area between the first Au pad film 51 and the second Au pad film 52.

The first pad electrode 40 includes a Pt pad film 55 interposed between the second Au pad film 52 and the third Au pad film 53. The Pt pad film 55 includes a Pt-based metal. Pure Pt (non-alloy Pt) and a Pt alloy are exemplified as the Pt-based metal. In this embodiment, the Pt pad film 55 includes a pure Pt film, and is interposed in the whole area between the second Au pad film 52 and the third Au pad film 53.

The Ni pad film 54 has a fourth pad thickness TP4. Preferably, the fourth pad thickness TP4 is less than the second pad thickness TP2 (TP4<TP2). Particularly preferably, the fourth pad thickness TP4 is less than the first pad thickness TP1 (TP4<TP1). The fourth pad thickness TP4 may be not less than 0.01 μm and not more than 0.1 μm. Preferably, the fourth pad thickness TP4 is not less than 0.025 μm and not more than 0.075 μm.

The Pt pad film 55 has a fifth pad thickness TP5. Preferably, the fifth pad thickness TP5 is less than the second pad thickness TP2 (TP5<TP2). Preferably, the fifth pad thickness TP5 is less than the first pad thickness TP1 (TP5<TP1). Particularly preferably, the fifth pad thickness TP5 is less than the fourth pad thickness TP4 (TP5<TP4). The fifth pad thickness TP5 may be not less than 10 nm and not more than 100 nm. The fifth pad thickness TP5 may be not less than 20 nm and not more than 50 nm.

The semiconductor light-emitting device 1A includes an uneven structure 56 formed at the first end surface 7 of the semiconductor layer 6. The uneven structure 56 is formed at a part, which is exposed from the first pad electrode 40, of the first end surface 7. The uneven structure 56 is formed by selectively digging down the second contact layer 18 so as to expose the second window layer 17. In this structure, a peripheral edge portion of the first pad electrode 40 projects to a region located outside the second contact layer 18 so as to face the second window layer 17 without sandwiching the second contact layer 18 between the second window layer 17 and the peripheral edge portion of the first pad electrode 40.

The second window layer 17 has a flat portion 57 in its part facing the peripheral edge portion of the first pad electrode 40. The flat portion 57 is a part that is smoother than the uneven structure 56. The uneven structure 56 diffuses light generated by the semiconductor layer 6. A projection width W of the first pad electrode 40 may be not less than 0.5 μm and not more than 5 μm. The projection width W may be not less than 1 μm and not more than 3 μm.

The semiconductor light-emitting device 1A includes a second pad electrode 58 covering the second main surface 4 of the substrate 2. The second pad electrode 58 covers the whole area of the second main surface 4, and is mechanically and electrically connected to the substrate 2. The second pad electrode 58 may include a Ti film and an Au film that are laminated in that order from a side of the second principal surface 4.

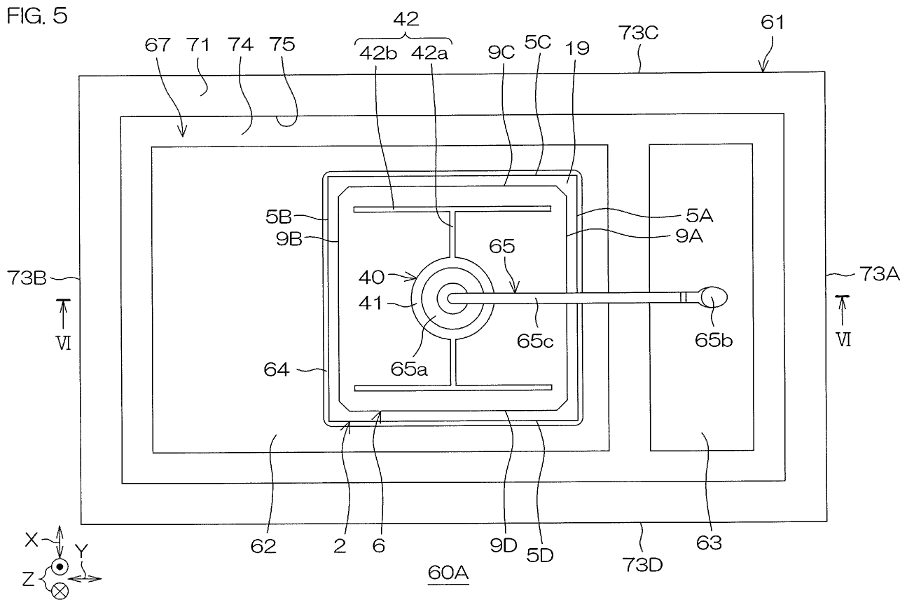

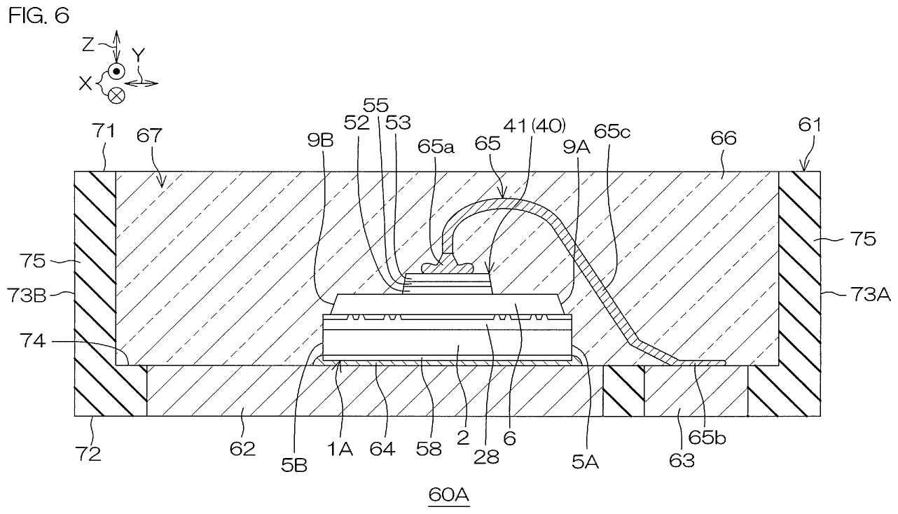

FIG. 5 is a plan view showing a first package 60A. FIG. 6 is a cross-sectional view taken along line VI-VI shown in FIG. 5. Referring to FIG. 5 and FIG. 6, the first package 60A includes a housing 61, a first electrode 62, a second electrode 63, the semiconductor light-emitting device 1A, a conductive joining material 64, a bonding wire 65, and a sealant 66.

The housing 61 has a containing space 67 exposed outwardly. The first electrode 62 is exposed inwardly and outwardly from the housing 61. The second electrode 63 is exposed inwardly and outwardly from the housing 61 at a position differing from that of the first electrode 62. The semiconductor light-emitting device 1A is arranged in the containing space 67 of the housing 61 in an orientation where light is emitted outwardly from the containing space 67.

The conductive joining material 64 electrically connects the semiconductor light-emitting device 1A and the first electrode 62. The bonding wire 65 electrically connects the semiconductor light-emitting device 1A and the second electrode 63. The sealant 66 seals the containing space 67 of the housing 61. A concrete structure of the first package 60A will be hereinafter described.

The housing 61 is formed in a rectangular parallelepiped shape. The housing 61 includes a first surface 71 on one side, a second surface 72 on the other side, and first to fourth sidewalls 73A to 73D connecting the first surface 71 and the second surface 72. The first surface 71 and the second surface 72 are each formed in a quadrangular shape (in this embodiment, rectangular shape) in the plan view.

The first sidewall 73A and the second sidewall 73B extend in the first direction X, and face each other in the second direction Y. The third sidewall 73C and the fourth sidewall 73D extend in the second direction Y, and face the first direction X. The housing 61 has the containing space 67 hollowed toward the second surface 72 in an inward portion of the first surface 71.

The first electrode 62 is embedded in the housing 61 so as to be exposed from at least both the second surface 72 and a bottom portion of the containing space 67 on one side (the second sidewall 73B side) in the second direction Y. The first electrode 62 is made of a metal (for example, Cu-made) pillar-shaped or plate-shaped member. The planar shape of the first electrode 62 is arbitrary. In this embodiment, the first electrode 62 includes its part formed in a quadrangular shape in the plan view.

The second electrode 63 is embedded in the housing 61 at a distance from the first electrode 62 so as to be exposed from at least both the second surface 72 and the bottom portion of the containing space 67 on the other side (first sidewall 73A side) in the second direction Y. The second electrode 63 is made of a metal (for example, Cu-made) pillar-shaped or plate-shaped member. The planar shape of the second electrode 63 is arbitrary. In this embodiment, the second electrode 63 includes its part formed in a quadrangular shape in the plan view.

The semiconductor light-emitting device 1A is arranged on the first electrode 62 in an orientation where the second pad electrode 58 is faced by the first electrode 62. Preferably, the semiconductor light-emitting device 1A is arranged at the middle of the housing 61 in the plan view. The conductive joining material 64 is interposed between the second pad electrode 58 and the first electrode 62, and electrically and mechanically connects the semiconductor light-emitting device 1A and the first electrode 62. The conductive joining material 64 is metal paste or solder.

The bonding wire 65 is connected to the first pad electrode 40 and to the second electrode 63. The bonding wire 65 includes at least one among an Au wire, a Cu wire, and an Al wire. The bonding wire 65 has one end portion 65a, one other end portion 65b, and a wire portion 65c.

The one end portion 65a is pressed and bonded to the first pad electrode 40 in a bump form (projection form). The other end portion 65b is pressed and bonded to the second electrode 63, and has its part that extends as a thin film along the second electrode 63. The wire portion 65c is formed integrally with the one end portion 65a and with the other end portion 65b, and linearly extends between the one end portion 65a and the other end portion 65b.

The sealant 66 is composed of an organic insulator (resin) having translucency or is a transparent organic insulator (resin). The sealant 66 fills the containing space 67 so as to cover the whole area of an exposed surface of the semiconductor light-emitting device 1A.

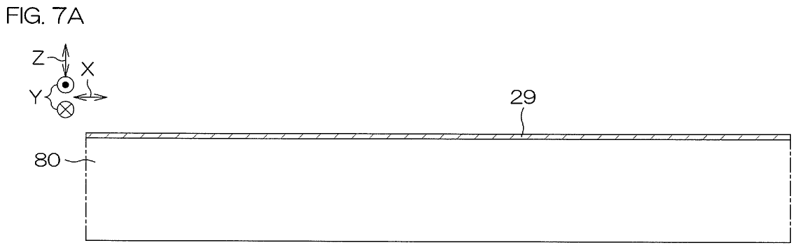

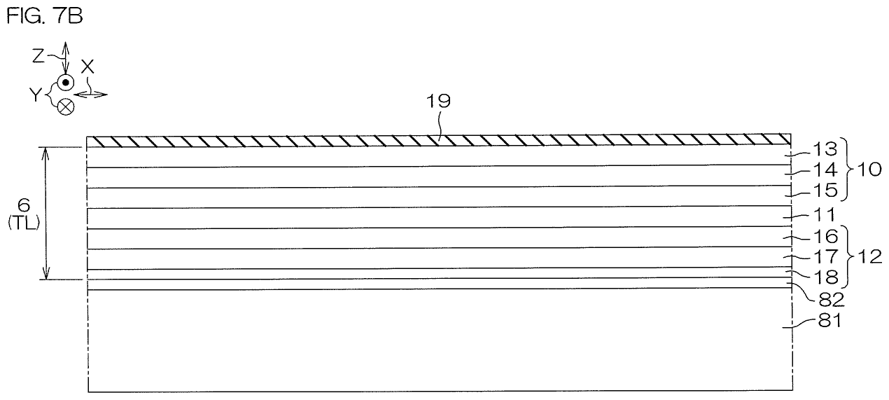

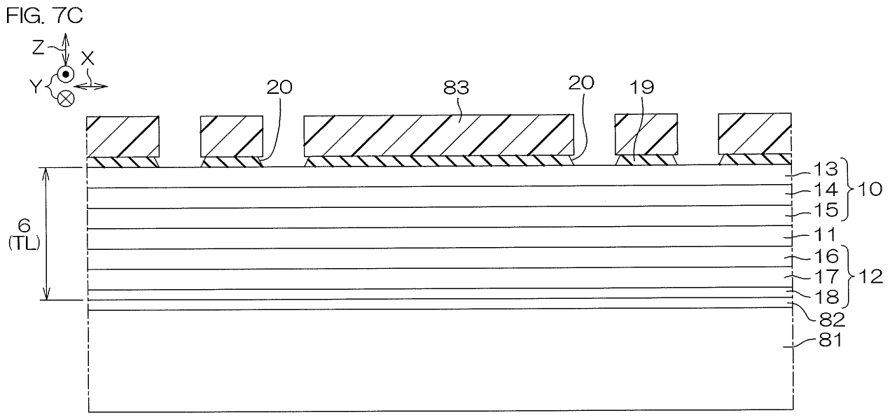

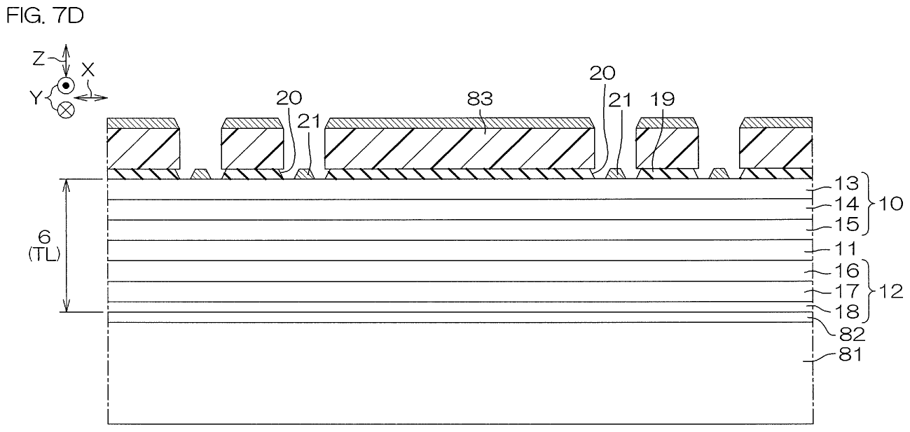

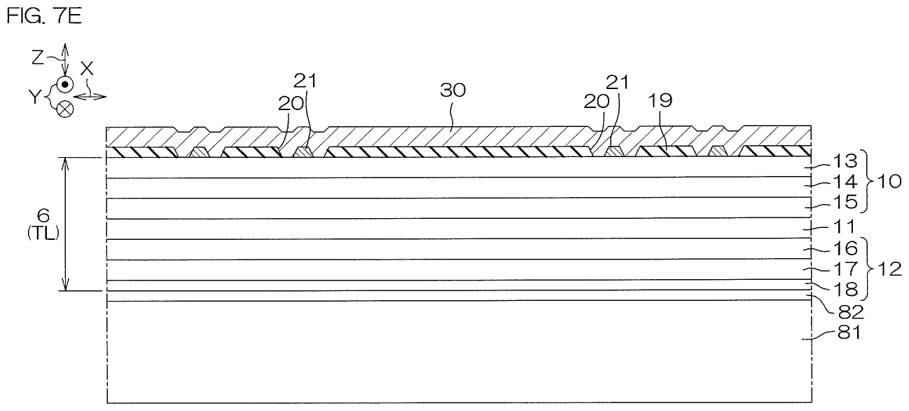

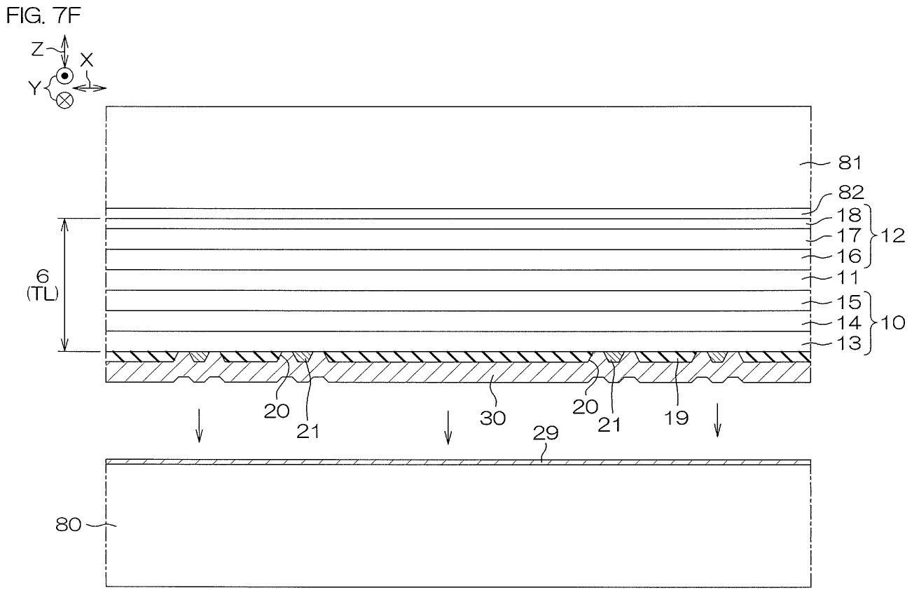

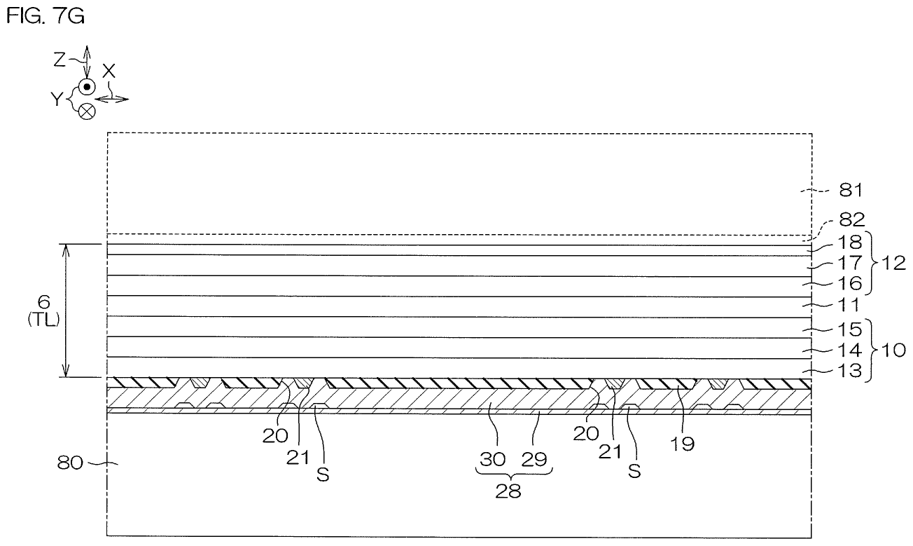

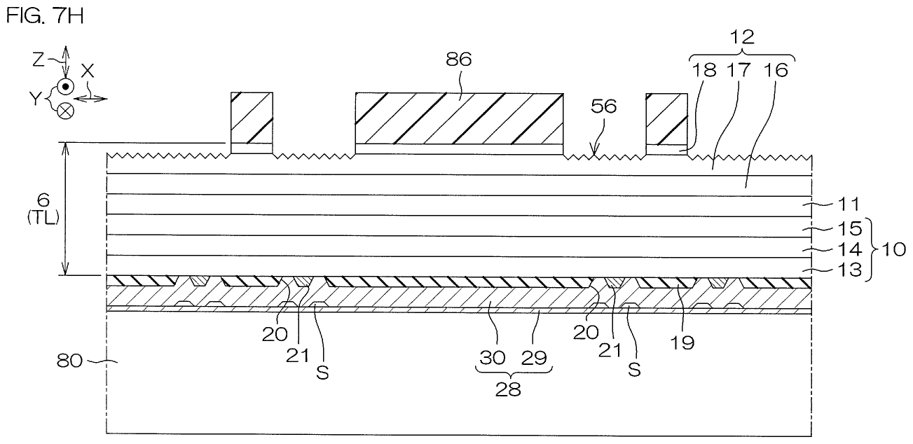

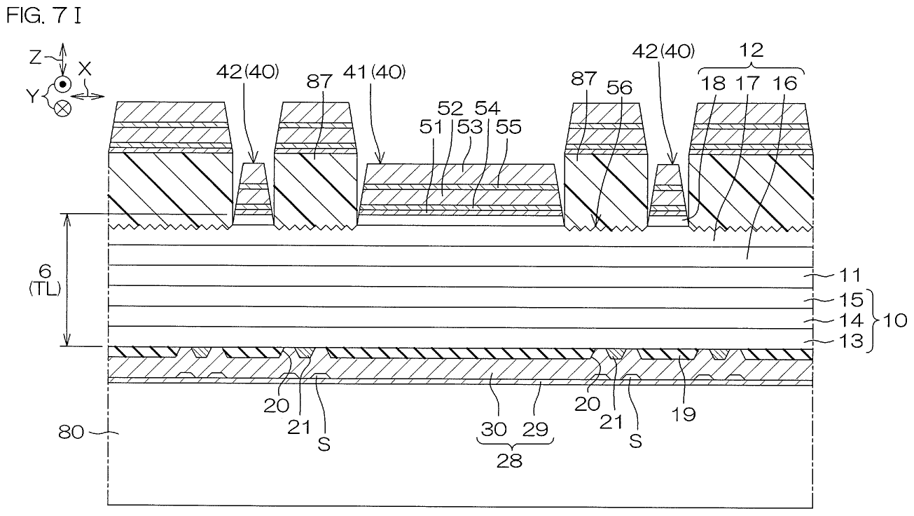

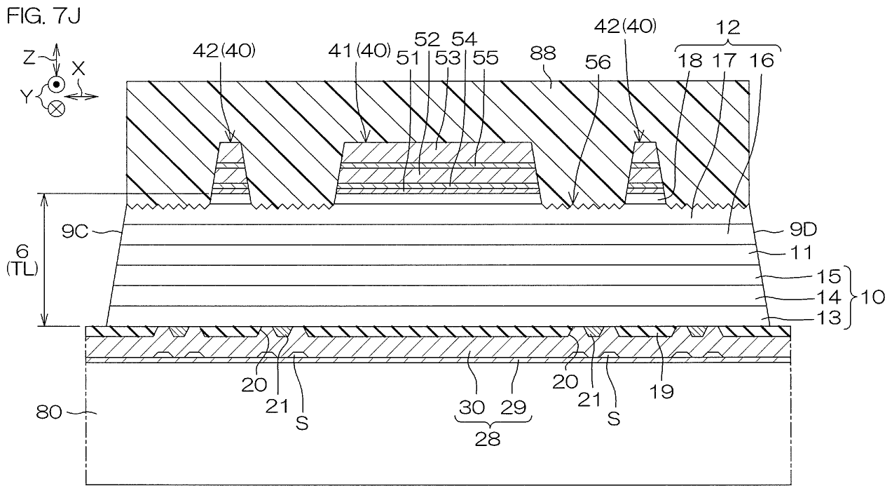

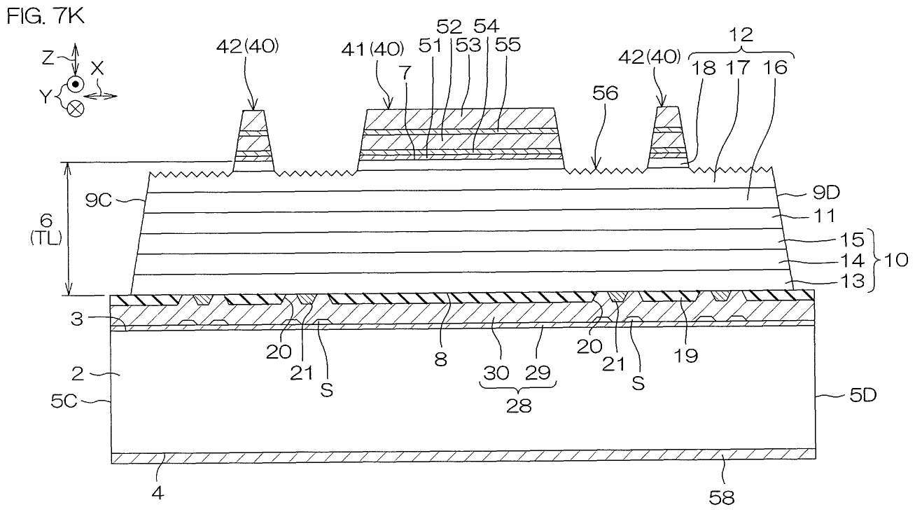

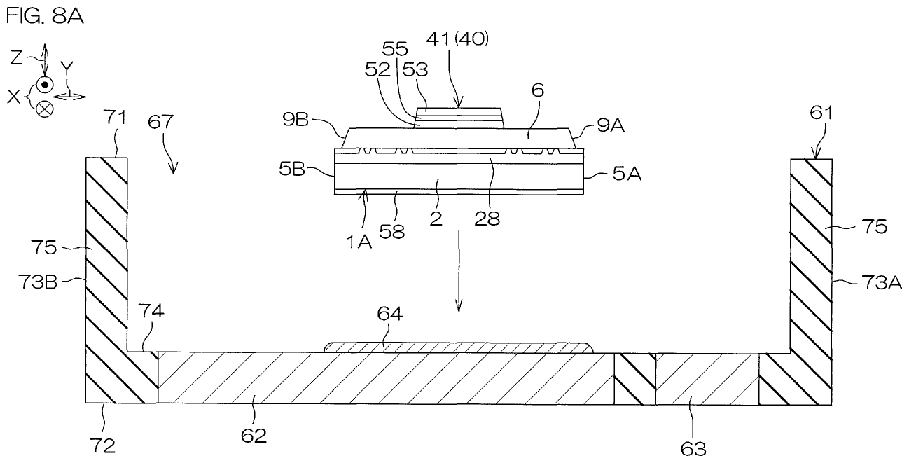

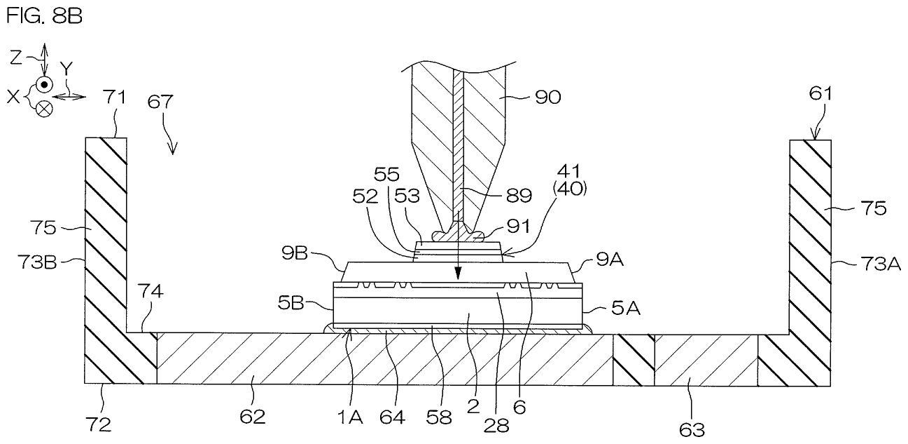

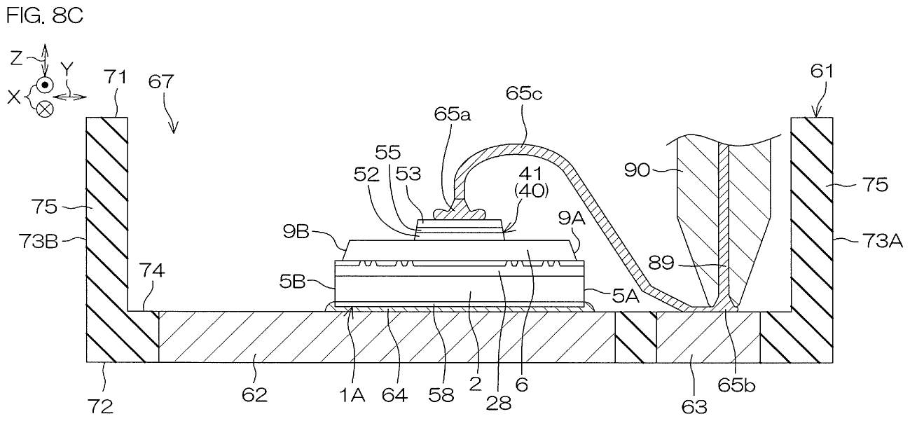

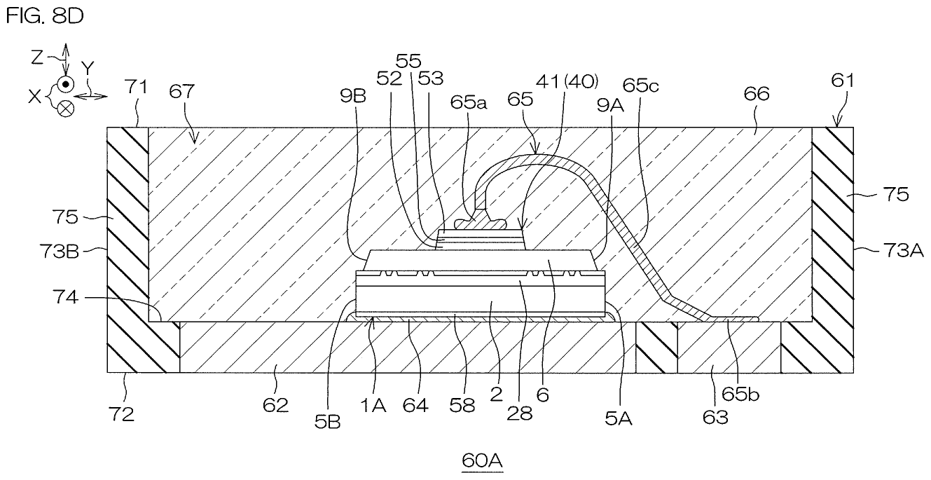

FIG. 7A to FIG. 7K are cross-sectional views each of which shows an example of a method for manufacturing the semiconductor light-emitting device 1A shown in FIG. 1. FIG. 8A to FIG. 8D are cross-sectional views each of which shows an example of a method for manufacturing the first package 60A shown in FIG. 5. The manufacturing process of the first package 60A is performed after the manufacturing process of the semiconductor light-emitting device 1A.

First, referring to FIG. 7A, a wafer 80 serving as a base of the substrate 2 is prepared. Next, the first metal layer 29 is laminated on the wafer 80. The first metal layer 29 may be formed by a sputtering method, a vapor deposition method, etc. This step includes a step of forming the first Ti film 36 and the first Au film 31 in that order from a side of the wafer 80. The first Au film 31 is formed with the first thickness T1, and the first Ti film 36 is formed with the sixth thickness T6 (see FIG. 3).

Next, referring to FIG. 7B, a support wafer 81 is prepared independently of the wafer 80. The support wafer 81 may be a GaAs wafer. Next, the semiconductor layer 6 is laminated on the support wafer 81 by an epitaxial growth method. The epitaxial growth method may be a molecular beam epitaxial growth method, a metalorganic vapor phase epitaxial growth method, etc.

This step includes a step of forming an etching stop layer 82, the second contact layer 18, the second window layer 17, the second cladding layer 16, the light-emitting layer 11, the first cladding layer 15, the first window layer 14, and the first contact layer 13 in that order from a side of the support wafer 81. The etching stop layer 82 is a compound semiconductor layer having an etching rate differing from that of the second contact layer 18. Next, the insulating film 19 is laminated on the semiconductor layer 6 by a CVD (chemical vapor deposition) method.

Next, referring to FIG. 7C, a first resist mask 83 having a predetermined pattern is formed on the insulating film 19. In the insulating film 19, the first resist mask 83 exposes regions in which the contact openings 20 are to be formed, and covers regions other than those regions. Next, unnecessary portions of the insulating film 19 are removed by an etching method through the first resist mask 83 until the semiconductor layer 6 is exposed. Hence, the contact openings 20 are formed.

Next, referring to FIG. 7D, the contact electrodes 21 are formed in the contact openings 20 by a lift-off method using the first resist mask 83. This step includes a step of forming the first conductor film 22, the second conductor film 23, and the third conductor film 24 in that order from the side of the semiconductor layer 6. The first resist mask 83 is removed afterwards.

Next, referring to FIG. 7E, the second metal layer 30 is formed on the insulating film 19. The second metal layer 30 may be formed by the sputtering method, the vapor deposition method, etc. This step includes a step of forming the fifth Au film 35, the fourth Au film 34, the third Au film 33, the second Ti film 37, and the second Au film 32 in that order from a side of the insulating film 19. The second to fifth Au films 32 to 35 are formed with the second to fifth thicknesses T2 to T5, respectively, and the second Ti film 37 is formed with the seventh thickness T7 (see FIG. 3).

Next, referring to FIG. 7F, the second metal layers 30 on the support wafer 81 side are joined to the first metal layer 29 on the wafer 80 side. The second metal layer 30 may be joined to the first metal layer 29 by a compression bonding method (for example, thermal compression bonding method). Hence, the metal layer 28 including the first and second metal layers 29 and 30 is formed between the substrate 2 and the semiconductor layer 6.

Next, referring to FIG. 7G, the support wafer 81 is removed by the etching method until the etching stop layer 82 is exposed. Preferably, the etching method is a wet etching method. Next, the etching stop layer 82 is removed by the etching method until the second semiconductor layer 12 (second contact layer 18) is exposed.

Next, referring to FIG. 7H, a second resist mask 86 having a predetermined pattern is formed on the second contact layer 18. In the second contact layer 18, the second resist mask 86 covers a region in which the first pad electrode 40 is to be arranged, and exposes regions other than this region.

Next, unnecessary portions of the second contact layer 18 are removed until the second window layer 17 is exposed, and frosting is applied onto the second window layer 17 by a frosting method using the etching method through the second resist mask 86. Preferably, the etching method is a wet etching method, and yet a dry etching method may be employed. Hence, the region in which the first pad electrode 40 is to be arranged is formed at the second contact layer 18, and, simultaneously, the uneven structure 56 is formed at the exposed portion of the second window layer 17. The second resist mask 86 is removed afterwards.

Next, referring to FIG. 7I, a third resist mask 87 having a predetermined pattern is formed on the second window layer 17. In the second contact layer 18, the third resist mask 87 exposes the region in which the first pad electrode 40 is to be formed, and covers regions other than this region. Preferably, the third resist mask 87 covers a peripheral edge portion of the second contact layer 18.

Next, the first pad electrode 40 is formed on the second contact layer 18 by the lift-off method using the third resist mask 87. The first pad electrode 40 may be formed by the sputtering method, the vapor deposition method, etc. This step includes a step of forming the first Au pad film 51, the Ni pad film 54, the second Au pad film 52, the Pt pad film 55, and the third Au pad film 53 in that order from the side of the semiconductor layer 6. The third resist mask 87 is removed afterwards.

Next, a part, which is exposed from the first pad electrode 40, of the second contact layer 18 is removed by a side etching method. Hence, a structure is formed in which the peripheral edge portion of the first pad electrode 40 projects to a region located outside the second contact layer 18.

Next, referring to FIG. 7J, a fourth resist mask 88 having a predetermined pattern is formed on the semiconductor layer 6 and on the first pad electrode 40. The fourth resist mask 88 covers a region in which the semiconductor layers 6 each of which has a truncated cone or pyramid shape are to be formed, and exposes regions other than this region. Next, unnecessary portions of the semiconductor layer 6 are removed by the etching method through the fourth resist mask 88 until the insulating film 19 is exposed. The etching method may be the wet etching method and/or the dry etching method. Hence, the truncated-cone-or-pyramid-shaped semiconductor layers 6 are formed. The fourth resist mask 88 is removed afterwards.

Next, referring to FIG. 7K, the second pad electrode 58 is formed at a main surface, which is located on the side opposite to the semiconductor layer 6, of the wafer 80. The second pad electrode 58 may be formed by the sputtering method, the vapor deposition method, etc. Thereafter, the wafer 80 is cut along regions between the truncated-cone-or-pyramid-shaped semiconductor layers 6, and the semiconductor light-emitting devices 1A are cut out. The semiconductor light-emitting device 1A is manufactured through steps including the above.

Next, referring to FIG. 8A, the manufacturing process of the first package 60A is performed. In the manufacturing process of the first package 60A, first, the housing 61 is prepared. Next, the semiconductor light-emitting device 1A is arranged on the first electrode 62 in an orientation where the second pad electrode 58 is faced by the first electrode 62. The second pad electrode 58 is joined to the first electrode 62 through the conductive joining material 64. The conductive joining material 64 may be beforehand formed on the first electrode 62.

Next, referring to FIG. 8B, a wire bonding step of the semiconductor light-emitting device 1A is performed. In this step, first, an initial ball 91 of a base wire 89 is joined to the first pad electrode 40 by means of a capillary 90 that supplies the base wire 89 serving as the bonding wire 65.

In this step, a load toward the semiconductor layer 6 is applied from the capillary 90 to the first pad electrode 40 through the initial ball 91, and, simultaneously, ultrasonic vibrations are applied from the capillary 90 to the first pad electrode 40 through the initial ball 91. Hence, the initial ball 91 is pressed and bonded to the first pad electrode 40, and the one end portion 65a of the bonding wire 65 is formed.

Next, referring to FIG. 8C, the base wire 89 is drawn out from the first pad electrode 40 side to the second electrode 63 side by means of the capillary 90. Hence, the wire portion 65c of the bonding wire 65 is formed. The base wire 89 is joined (pressed and bonded) to the second electrode 63, and is then separated from the second electrode 63. Hence, the other end portion 65b of the bonding wire 65 is formed.

Next, referring to FIG. 8D, the sealant 66 is supplied to the containing space 67 of the housing 61, and the semiconductor light-emitting device 1A is sealed by the sealant 66. The first package 60A is manufactured through steps including the above.

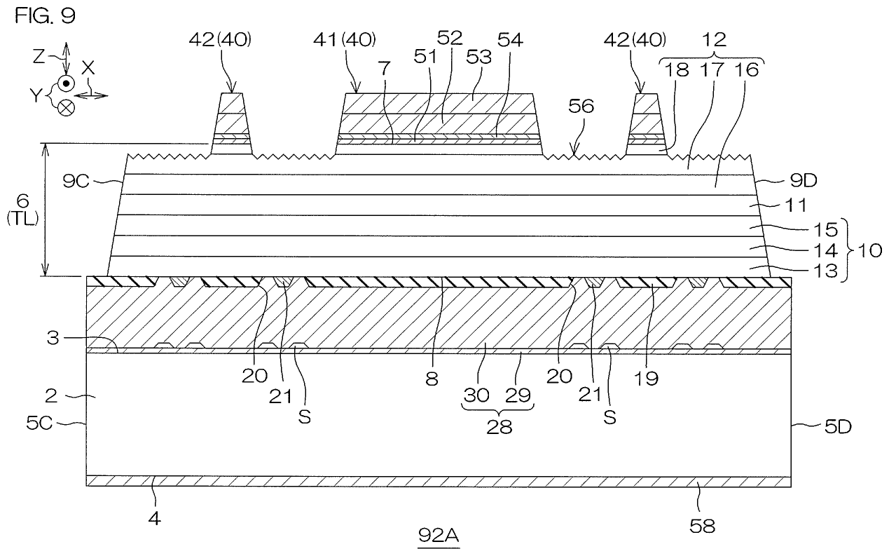

FIG. 9 is a cross-sectional view showing a semiconductor light-emitting device 92A according to a first reference mode. The semiconductor light-emitting device 92A has the same structure as the semiconductor light-emitting device 1A with respect to the configuration of the metal layer 28 and configurations other than the first pad electrode 40. In the metal layer 28 according to the semiconductor light-emitting device 92A, the total thickness TA of the first to fifth Au films 31 to 35 is increased. In the first pad electrode 40 according to the semiconductor light-emitting device 92A, the Pt pad film 55 is removed, and the total thickness TP of the first to third Au pad films 51 to 53 is increased.

The first thickness T1 of the first Au film 31 exceeds 0.125 μm. For example, the first thickness T1 is not less than 0.2 μm and not more than 0.5 μm. The second thickness T2 of the second Au film 32 exceeds 0.125 μm. For example, the second thickness T2 is not less than 0.2 μm and not more than 0.5 μm. The third thickness T3 of the third Au film 33 exceeds 0.1 μm. For example, the third thickness T3 is not less than 0.2 μm and not more than 0.5 μm.

The fourth thickness T4 of the fourth Au film 34 exceeds 0.15 μm. For example, the fourth thickness T4 is not less than 0.2 μm and not more than 0.5 μm. The fifth thickness T5 of the fifth Au film 35 exceeds 0.15 μm. For example, the fifth thickness T5 is not less than 0.2 μm and not more than 0.5 μm. The thickness ratio TA/TL of the total thickness TA of the first to fifth Au metal films with respect to the layer thickness TL of the semiconductor layer 6 exceeds 0.25.

The first pad thickness TP1 of the first Au pad film 51 is set to become substantially equal to the first pad thickness TP1 of the first Au pad film 51 according to the semiconductor light-emitting device 1A. The second pad thickness TP2 of the second Au pad film 52 exceeds 1 μm. For example, the second pad thickness TP2 of the second Au pad film 52 is not less than 1.5 μm and not more than 3 μm. The third pad thickness TP3 of the third Au pad film 53 is set to become substantially equal to the third pad thickness TP3 of the third Au pad film 53 according to the semiconductor light-emitting device 1A.

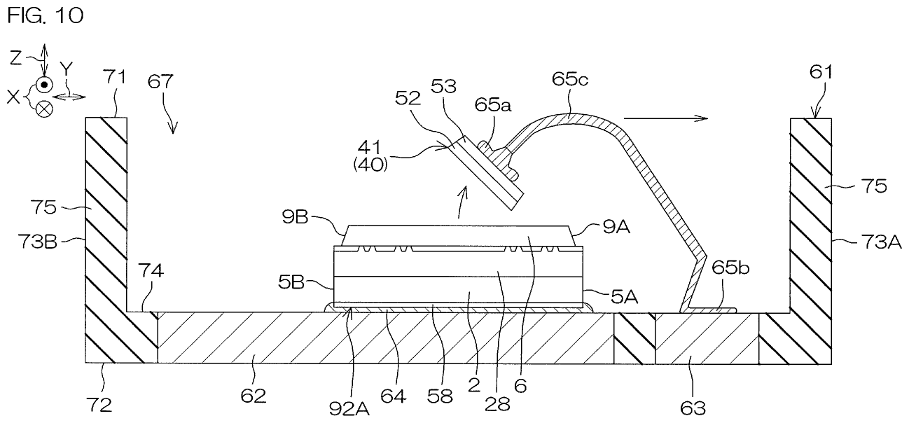

FIG. 10 is a cross-sectional view showing a mode taken when a peel test of the bonding wire 65 is performed with respect to the semiconductor light-emitting device 92A shown in FIG. 9. In the peel test, a tensile force in the second direction Y was applied to the one end portion 65a of the bonding wire 65 (hereinafter, the same applies). Referring to FIG. 10, in the peel test according to the semiconductor light-emitting device 92A, the one end portion 65a of the bonding wire 65 was peeled off from the semiconductor layer 6 together with the first pad electrode 40. This peel mode is hereinafter referred to as a “peel-off mode.”

In the semiconductor light-emitting device 92A, the total thickness TP of the first to third Au pad films 51 to 53 according to the first pad electrode 40 is set to be comparatively thick. Therefore, a force in the lateral direction (first and second directions X and Y) caused by ultrasonic vibrations strongly acts on the first pad electrode 40 in the wire bonding step (see FIG. 8B). As a result, it is conceivable that the adhesive force of the first pad electrode 40 with respect to the semiconductor layer 6 decreased and that the first pad electrode 40 peeled off together with the bonding wire 65 in the peel test.

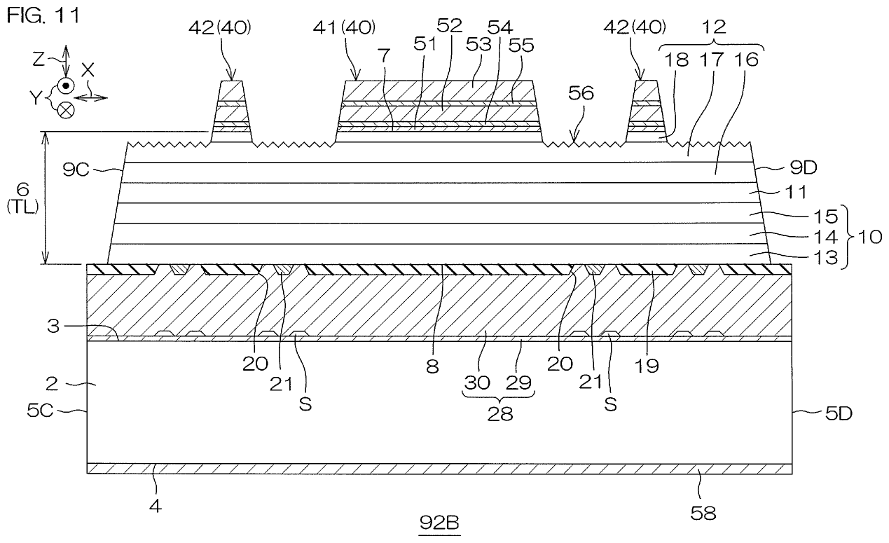

FIG. 11 is a cross-sectional view showing a semiconductor light-emitting device 92B according to a second reference mode. The semiconductor light-emitting device 92B has the same structure as the semiconductor light-emitting device 1A with respect to configurations other than the metal layer 28. The configuration of the metal layer 28 according to the semiconductor light-emitting device 92B is the same as the configuration of the metal layer 28 according to the semiconductor light-emitting device 92A mentioned above.

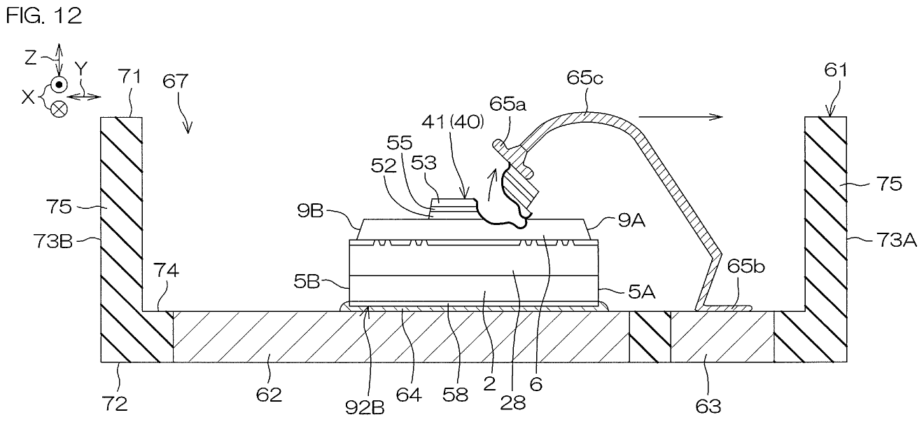

FIG. 12 is a cross-sectional view showing a mode taken when a peel test of the bonding wire 65 is performed with respect to the semiconductor light-emitting device 92B shown in FIG. 11. Referring to FIG. 12, in the peel test according to the semiconductor light-emitting device 92B, the one end portion 65a of the bonding wire 65 peeled off from the semiconductor layer 6 together with a part of the first pad electrode 40 so that a part of the semiconductor layer 6 is gouged out. This peel mode is hereinafter referred to as a “gouge-out mode.”

In the semiconductor light-emitting device 92B, the total thickness TP of the first to third Au pad films 51 to 53 according to the first pad electrode 40 is set to be comparatively thin. Also, in the semiconductor light-emitting device 92B, the Pt pad film 55 is interposed between the first Au pad film 51 and the second Au pad film 52. The Pt-based metal is a metal harder than the Au-based metal.

Hence, a force in the lateral direction (first and second directions X and Y) caused by ultrasonic vibrations is prevented from strongly acting on the first pad electrode 40 in the wire bonding step (see FIG. 8B). As a result, a decrease in the adhesive force of the first pad electrode 40 with respect to the semiconductor layer 6 is suppressed, and the “peel-off mode” is suppressed.

It is conceivable that the “gouge-out mode” results from a load applied from the capillary 90 to the first pad electrode 40 and results from the total thickness TA of the first to fifth Au films 31 to 35 that are lower in hardness than the semiconductor layer 6. In other words, a flexure occurs in the semiconductor layer 6 because of the flexure of the first to fifth Au films 31 to 35 when a load toward the semiconductor layer 6 is applied from the capillary 90 to the first pad electrode 40. Therefore, it is conceivable that fine defects (crystal lattice defects, cracks, etc.) occurred in a connection portion of the first pad electrode 40 in the semiconductor layer 6, and, as a result, the “gouge-out mode” occurred resulting from these defects.

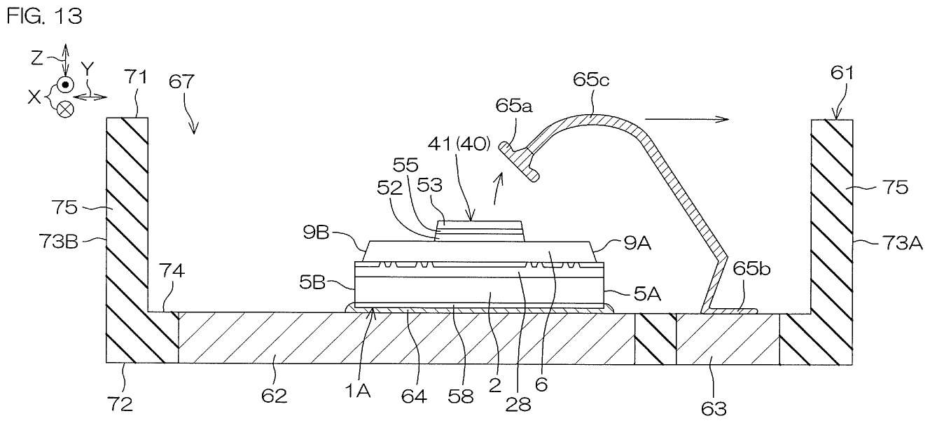

FIG. 13 is a cross-sectional view showing a mode taken when a peel test of the bonding wire 65 is performed with respect to the semiconductor light-emitting device 1A shown in FIG. 1. Referring to FIG. 13, the one end portion 65a of the bonding wire 65 peeled off from the first pad electrode 40 in the peel test according to the semiconductor light-emitting device 1A. In other words, both the “peel-off mode” and the “gouge-out mode” were prevented from occurring in the semiconductor light-emitting device 1A.

As described above, the semiconductor light-emitting device 1A includes the substrate 2, the semiconductor layer 6, and the metal layer 28. The semiconductor layer 6 is laminated on the substrate 2, and generates light. The metal layer 28 has a laminated structure including the first to fifth Au films 31 to 35, and is interposed between the substrate 2 and the semiconductor layer 6. In the thus formed structure, the thickness ratio of the total thickness of the Au films to the thickness of the semiconductor layer 6 is not less than 0.03 and not more than 0.25.

This structure makes it possible to provide the semiconductor light-emitting device 1A capable of restricting the flexure of the semiconductor layer 6 caused by a load. For example, if the first pad electrode 40 is formed in the thus formed structure and if a peel test of the bonding wire 65 is performed with respect to the first pad electrode 40, it is possible to suppress the occurrence of the “peel-off mode” and the “gouge-out mode.” Therefore, it is possible to provide the semiconductor light-emitting device 1A capable of improving reliability.

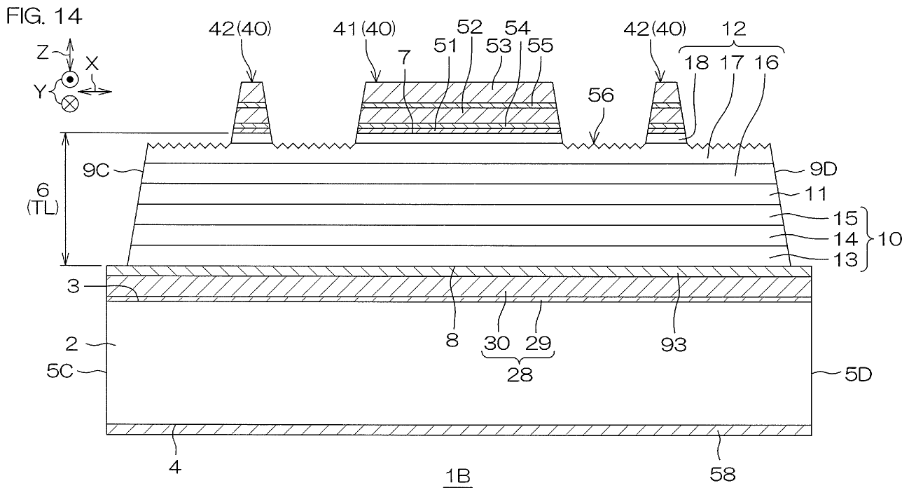

FIG. 14 is a cross-sectional view of a semiconductor light-emitting device 1B according to a second embodiment. The semiconductor light-emitting device 1B includes a translucent conductor layer 93, instead of the insulating film 19 and the contact electrodes 21. The translucent conductor layer 93 includes indium tin oxide (ITO). In other words, preferably, the translucent conductor layer 93 includes an electroconductive oxide film. The translucent conductor layer 93 may be formed by the vapor deposition method in the step of FIG. 7B mentioned above.

Preferably, in this structure, the fourth Au film 34 consists of an AuCr alloy film including AuCr as an example of the Au alloy. In this embodiment, the fourth Au film 34 is provided as a supply source that supplies Cr to the third Au film 33 and to the fifth Au film 35. Therefore, the third Au film 33 may include Cr that has been diffused from the fourth Au film 34. Also, the fifth Au film 35 may include Cr that has been diffused from the fourth Au film 34.

In this case, the second Ti film 37 suppresses the diffusion of Cr to the first Au film 31 and to the second Au film 32. In this embodiment, the dissimilar insulating film 38 includes CrO (chromium oxide) in which Cr that has been diffused from the fourth Au film 34 is combined with O (oxygen) of the insulating film 19. The dissimilar insulating film 38 increases the adhesive force of the metal layer 28 (specifically, fifth Au film 35) with respect to the insulating film 19. As described above, the same effect as the effect of the semiconductor light-emitting device 1A is also fulfilled by the semiconductor light-emitting device 1B.

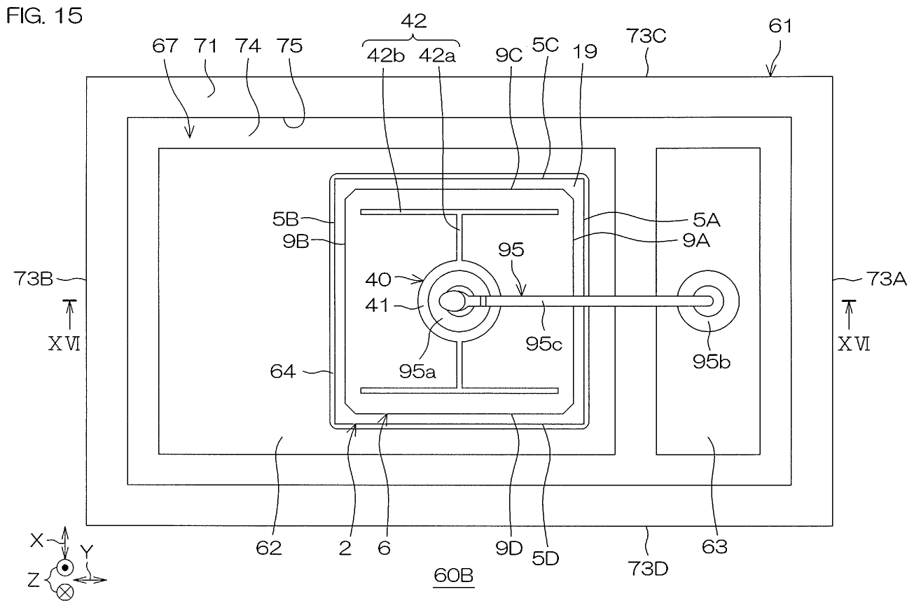

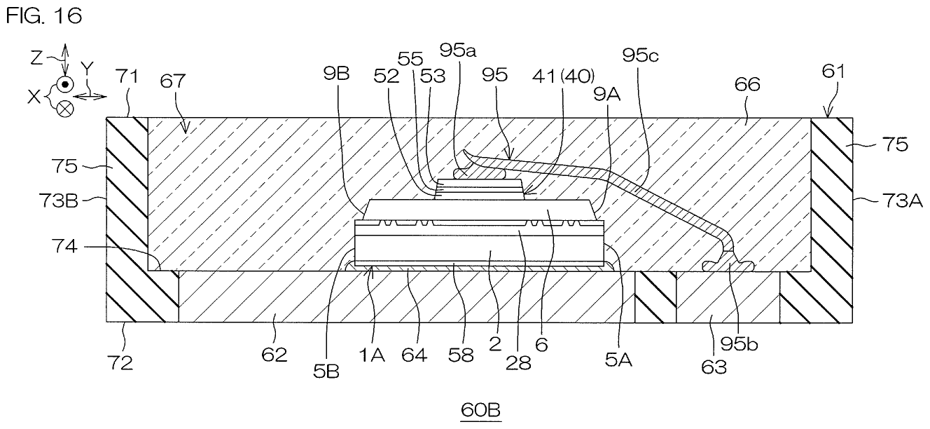

FIG. 15 is a plan view showing a second package 60B. FIG. 16 is a cross-sectional view taken along line XVI-XVI shown in FIG. 15. The second package 60B differs from the first package 60A in the point that the second package 60B has a bonding wire 95 instead of the bonding wire 65. The bonding wire 95 includes one end portion 95a, one other end portion 95b, and a wire portion 95c. The one end portion 95a is pressed and bonded to the first pad electrode 40 in a bump form (projection form). The other end portion 95b is pressed and bonded to the second electrode 63 in a bump form (projection form). The wire portion 95c linearly extends between the one end portion 95a and the other end portion 95b.

In this embodiment, the wire portion 95c has one end that is formed separately from the one end portion 95a and one other end formed integrally with the other end portion 95b. The wire portion 95c extends from the other end portion 95b toward the one end portion 95a, and is connected (pressed and bonded) to the one end portion 95a. A connection portion (pressed/bonded portion) of the wire portion 95c with respect to the one end portion 95a has its part that extends as a thin film along the one end portion 95a. With this bonding wire 95, it is possible to make the height of the wire portion 95c smaller than the wire portion 65c of the bonding wire 65. This makes it possible to downsize the housing 61.

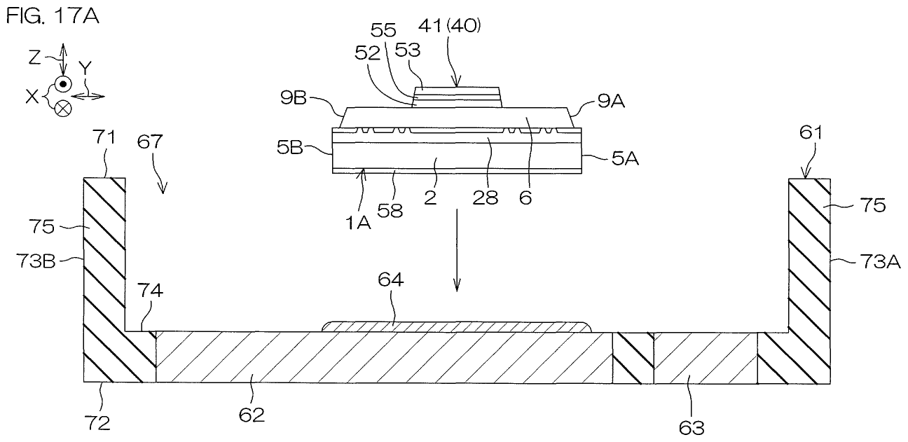

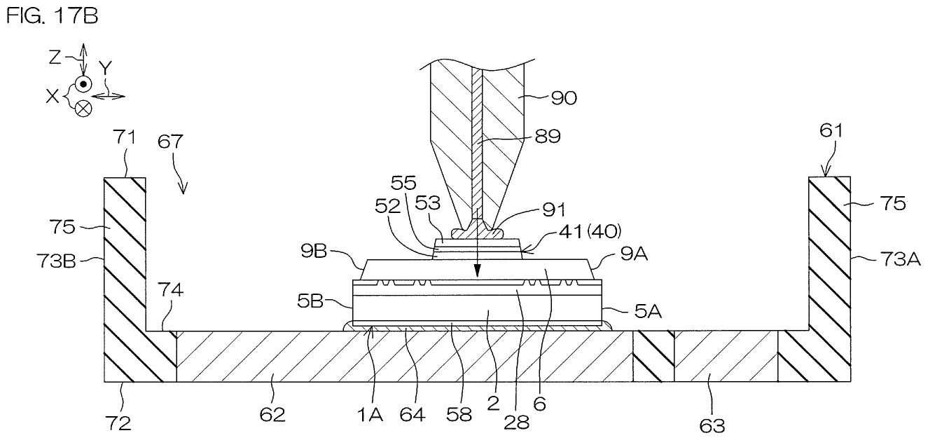

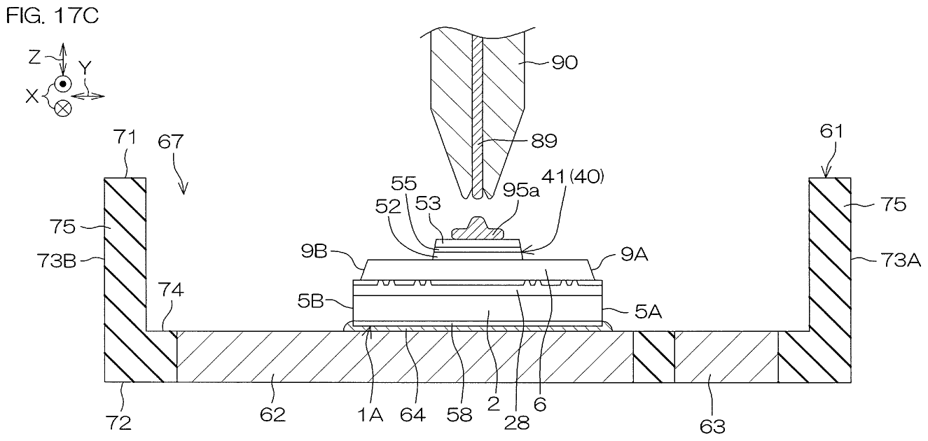

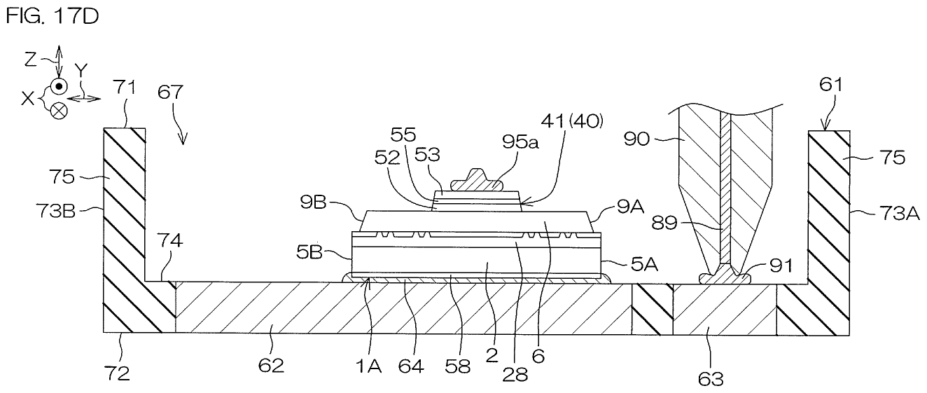

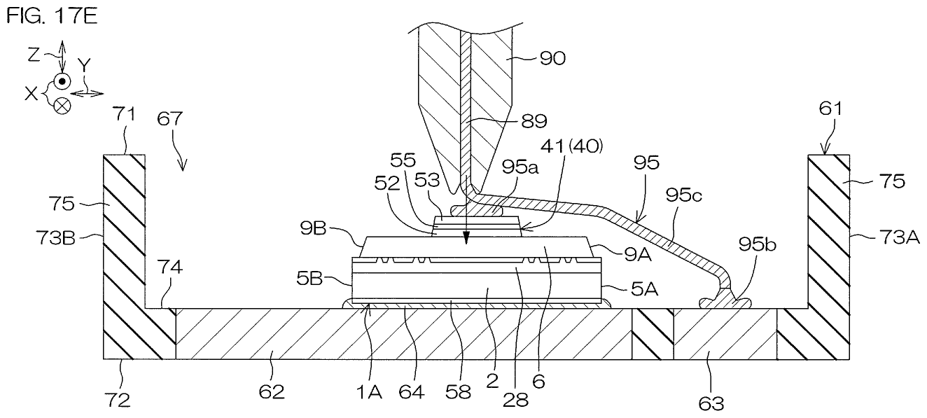

FIG. 17A to FIG. 17E are cross-sectional views each of which shows an example of a method for manufacturing the second package 60B shown in FIG. 15. Referring to FIG. 17A, first, the housing 61 is prepared in the manufacturing process of the second package 60B. Next, the semiconductor light-emitting device 1A is arranged on the first electrode 62 in an orientation where the second pad electrode 58 is faced by the first electrode 62. The second pad electrode 58 is joined to the first electrode 62 through the conductive joining material 64. The conductive joining material 64 may be beforehand formed on the first electrode 62.

Next, referring to FIG. 17B, the initial ball 91 of the base wire 89 is joined to the first pad electrode 40. In this step, a load toward the semiconductor layer 6 is applied from the capillary 90 to the first pad electrode 40 through the initial ball 91, and, simultaneously, ultrasonic vibrations are applied from the capillary 90 to the first pad electrode 40 through the initial ball 91. Hence, the initial ball 91 is pressed and bonded to the first pad electrode 40. Next, referring to FIG. 17C, the initial ball 91 is separated from the base wire 89. Hence, the one end portion 95a having a bump form is formed.

Next, referring to FIG. 17D, another initial ball 91 is joined (pressed and bonded) to the second electrode 63 through the same step as the step of FIG. 17B. Hence, the other end portion 95b having a bump form is formed. Next, referring to FIG. 17E, the base wire 89 is drawn out from the other end portion 95b side to the one end portion 95a side by means of the capillary 90, and is joined to the one end portion 95a.

Next, a load toward the semiconductor layer 6 is again applied from the capillary 90 to the first pad electrode 40 through the base wire 89, and, simultaneously, ultrasonic vibrations are again applied from the capillary 90 to the first pad electrode 40 through the base wire 89. Hence, the base wire 89 is pressed and bonded to the one end portion 95a.

The base wire 89 is separated from the one end portion 95a afterwards. Hence, the wire portion 95c is formed. Thereafter, the sealant 66 is supplied to the containing space 67 of the housing 61, and the semiconductor light-emitting device 1A is sealed by the sealant 66. The second package 60B is manufactured through steps including the above.

In the second package 60B, the load is applied to the semiconductor layer 6 a plurality of times as described above, and yet, even in this case, it is possible to suppress the “peel-off mode” and the “gouge-out mode” in the peel test. In other words, with the semiconductor light-emitting device 1A, it is possible to have a structure that is firm against the “peel-off mode” and the “gouge-out mode,” and therefore it is possible to have high reliability even in a state of being mounted in the second package 60B.

Each of the embodiments mentioned above can be carried out in still other modes. For example, in each of the aforementioned embodiments, a mode where the first pad electrode 40 includes the first to third Au pad films 51 to 53 was described. However, the number of laminated layers of the Au pad films included in the first pad electrode 40 is not limited to three layers as long as the “peel-off mode” is suppresses. Therefore, the first pad electrode 40 may include four or more layers of the Au pad films.

In each of the aforementioned embodiments, a mode where the second metal layer 30 includes the second to fifth Au films 32 to 35 was described. However, the number of laminated layers of the Au films included in the second metal layer 30 is not limited to four layers as long as the “peel-off mode” and the “gouge-out mode” are suppressed. Therefore, the second metal layer 30 may include five or more layers of the Au films.

In each of the aforementioned embodiments, a mode where the first pad electrode 40 includes the main body portion 41 and the arm portion 42 was described. However, the first pad electrode 40 consisting of only the main body portion 41 may be formed. Also, the first pad electrode 40 including four or more arm portions 42 led out in the first and second directions X and Y may be formed.

The semiconductor light-emitting devices 1A and 1B may include an outer surface insulating film covering an outer surface of the semiconductor layer 6 in each of the aforementioned embodiments. Preferably, the outer surface insulating film covers the first end surface 7 of the semiconductor layer 6 and the first to fourth peripheral walls 9A to 9D as a film so as to expose the first pad electrode 40.

The outer surface insulating film may include at least one of a silicon oxide film and a silicon nitride film. Preferably, the outer surface insulating film has a single layer structure consisting of a silicon nitride film. Preferably, the outer surface insulating film covers a part, which projects outwardly from the first to fourth peripheral walls 9A to 9D, of the insulating film 19 in the case of the first embodiment. Preferably, the outer surface insulating film covers a part, which projects outwardly from the first to fourth peripheral walls 9A to 9D, of the translucent conductor layer 93 in the case of the second embodiment.

In each of the aforementioned embodiments, an example was described in which the first conductivity type is a p-type, and the second conductivity type is an n-type. However, the first conductivity type may be an n-type, and the second conductivity type may be a p-type. A concrete configuration in this case can be obtained by replacing the p-type layer with the n-type layer and, simultaneously, by replacing the n-type layer with the p-type layer in the foregoing description.

In each of the aforementioned embodiments, the first and second directions X and Y are determined by the extending direction of the first to fourth side surfaces 5A to 5D of the substrate 2. However, the first and second directions X and Y may be arbitrary directions as long as the relationship of intersecting each other (specifically, orthogonal to each other) is maintained.

Characteristic examples extracted from this description and from the drawings are hereinafter shown. Hereinafter, alphanumeric characters in parentheses represent corresponding components, etc., in the aforementioned embodiments, and yet this representation does not denote that the scope of each clause is limited to the embodiments.

[A1] A semiconductor light-emitting device (1A, 1B) comprising: a substrate (2); a semiconductor layer (6) that is laminated on the substrate (2) and that generates light; and a metal layer (28) that is interposed between the substrate (2) and the semiconductor layer (6) and that has a laminated structure including Au films (31 to 35) each of which is made of an Au-based metal, wherein a ratio (TA/TL) of a total thickness (TA) of the Au films (31 to 35) with respect to a thickness (TL) of the semiconductor layer (6) is not less than 0.03 and not more than 0.25.

[A2] The semiconductor light-emitting device (1A, 1B) according to A1, wherein the thickness (TL) of the semiconductor layer (6) is not less than 4 μm and not more than 10 μm, and the total thickness (TA) of the Au films (31 to 35) is not less than 0.3 μm and not more than 1 μm.

[A3] The semiconductor light-emitting device (1A, 1B) according to A1 or A2, wherein the ratio (TA/TL) of the total thickness (TA) of the Au films (31 to 35) with respect to the thickness (TL) of the semiconductor layer (6) is not less than 0.04 and not more than 0.08.

[A4] The semiconductor light-emitting device (1A, 1B) according to A3, wherein the thickness (TL) of the semiconductor layer (6) is not less than 6 μm and not more than 9 μm, and the total thickness (TA) of the Au films (31 to 35) is not less than 0.4 μm and not more than 0.5 μm.

[A5] The semiconductor light-emitting device (1A, 1B) according to any one of A1 to A4, wherein the metal layer (28) includes a first Au film (31), a second Au film (32), a third Au film (33), a fourth Au film (34), and a fifth Au film (35) that are laminated in that order from a side of the substrate (2), and the total thickness (TA) of the Au films (31 to 35) is a total value of a thickness (T1) of the first Au film (31), a thickness (T2) of the second Au film (32), a thickness (T3) of the third Au film (33), a thickness (T4) of the fourth Au film (34), and a thickness (T5) of the fifth Au film (35).

[A6] The semiconductor light-emitting device (1A, 1B) according to A5, wherein the first Au film (31) is a first Au junction film, the second Au film (32) is a second Au junction film pressed and bonded to the first Au film (31), the third Au film (33) is a first Au light reflecting film, the fourth Au film (34) is an Au alloy film including an AuBe alloy or an AuCr alloy, and the fifth Au film (35) is a second Au light reflecting film.

[A7] The semiconductor light-emitting device (1A, 1B) according to A5 or A6, wherein a total thickness of the third Au film (33), the fourth Au film (34), and the fifth Au film (35) is equal to or more than a total thickness of the first Au film (31) and the second Au film (32).

[A8] The semiconductor light-emitting device (1A, 1B) according to any one of A5 to A7, wherein the thickness (T1) of the first Au film (31) is not less than 0.075 μm and not more than 0.125 μm, the thickness (T2) of the second Au film (32) is not less than 0.075 μm and not more than 0.125 μm, the thickness (T3) of the third Au film (33) is not less than 0.01 μm and not more than 0.1 μm, the thickness (T4) of the fourth Au film (34) is not less than 0.05 μm and not more than 0.15 μm, and the thickness (T5) of the fifth Au film (35) is not less than 0.05 μm and not more than 0.15 μm.

[A9] The semiconductor light-emitting device (1A, 1B) according to any one of A1 to A8, further comprising: a pad electrode (40) that is laminated on the semiconductor layer (6) and that has a laminated structure including Au pad films (51 to 53) each of which is made of an Au-based metal.

[A10] The semiconductor light-emitting device (1A, 1B) according to A9, wherein a total thickness (TP) of the Au pad films (51 to 53) exceeds the total thickness (TA) of the Au films (31 to 35).

[A11] The semiconductor light-emitting device (1A, 1B) according to A10, wherein the pad electrode (40) includes a first Au pad film (51), a second Au pad film (52), and a third Au pad film (53) that are laminated in that order from a side of the semiconductor layer (6), and the total thickness (TP) of the Au pad films (51 to 53) is a total value of a thickness (TP1) of the first Au pad film (51), a thickness (TP2) of the second Au pad film (52), and a thickness (TP3) of the third Au pad film (53).

[A12] The semiconductor light-emitting device (1A, 1B) according to A11, wherein the thickness (TP1) of the first Au pad film (51) is not less than 0.05 μm and not more than 0.1 μm, the thickness (TP2) of the second Au pad film (52) is not less than 0.1 μm and not more than 1 μm, and the thickness (TP3) of the third Au pad film (53) is not less than 1 μm and not more than 3 μm.

[A13] The semiconductor light-emitting device (1A, 1B) according to A11 or A12, wherein the pad electrode (40) includes a Pt pad film (55) that is interposed between the second Au pad film (52) and the third Au pad film (53) and that is made of a Pt-based metal.

[A14] The semiconductor light-emitting device (1A, 1B) according to any one of A9 to A13, wherein the pad electrode (40) has a main body portion (41) formed in a circular shape as viewe in plan and an arm portion (42) linearly led out from the main body portion (41).

[A15] The semiconductor light-emitting device (1A, 1B) according to A14, wherein the main body portion (41) of the pad electrode (40) has a width of not less than 80 μm and not more than 120 μm as viewed in plan.

[A16] The semiconductor light-emitting device (1A, 1B) according to any one of A1 to A15, further comprising: an insulating film (19) that is interposed between the substrate (2) and the semiconductor layer (6) so as to cover the semiconductor layer (6) and that has a contact opening (20) by which the semiconductor layer (6) is exposed; and a contact electrode (21) arranged in the contact opening (20) so as to be electrically connected to the semiconductor layer (6); wherein the metal layer (28) is interposed between the insulating film (19) and the substrate (2) so as to be electrically connected to the contact electrode (21).

[A17] The semiconductor light-emitting device (1A, 1B) according to A16, wherein the insulating film (19) includes at least one of a silicon oxide film and a silicon nitride film.

[A18] The semiconductor light-emitting device (1A, 1B) according to any one of A1 to A15, further comprising: a translucent conductor layer (93) interposed between the metal layer (28) and the semiconductor layer (6) so as to be electrically connected to the metal layer (28) and the semiconductor layer (6).

[A19] The semiconductor light-emitting device (1A, 1B) according to any one of A1 to A18, wherein the substrate (2) is made of a silicon substrate.

[A20] The semiconductor light-emitting device (1A, 1B) according to any one of A1 to A19, wherein the semiconductor layer (6) is made of a compound semiconductor layer.

Although the embodiments have been described in detail, these embodiments are merely concrete examples used to clarify the technical contents of the present invention, and the present invention should not be interpreted by being limited to these concrete examples, and the scope of the present invention is limited solely by the appended claims.

What is claimed is:

1. A semiconductor light-emitting device comprising:
a substrate;
a semiconductor layer that is laminated on the substrate and that generates light; and
a metal layer that is interposed between the substrate and the semiconductor layer and that has a laminated structure including Au films each of which is made of an Au-based metal;
wherein a ratio of a total thickness of the Au films with respect to a thickness of the semiconductor layer is not less than 0.03 and not more than 0.25.

2. The semiconductor light-emitting device according to claim 1,
wherein the thickness of the semiconductor layer is not less than 4 μm and not more than 10 μm, and
the total thickness of the Au films is not less than 0.3 μm and not more than 1 μm.

3. The semiconductor light-emitting device according to claim 1,
wherein the ratio of the total thickness of the Au films with respect to the thickness of the semiconductor layer is not less than 0.04 and not more than 0.08.

4. The semiconductor light-emitting device according to claim 3,
wherein the thickness of the semiconductor layer is not less than 6 μm and not more than 9 μm, and
the total thickness of the Au films is not less than 0.4 μm and not more than 0.5 μm.

5. The semiconductor light-emitting device according to claim 1,
wherein the metal layer includes a first Au film, a second Au film, a third Au film, a fourth Au film, and a fifth Au film that are laminated in that order from a side of the substrate, and
the total thickness of the Au films is a total value of a thickness of the first Au film, a thickness of the second Au film, a thickness of the third Au film, a thickness of the fourth Au film, and a thickness of the fifth Au film.

6. The semiconductor light-emitting device according to claim 5,
wherein the first Au film is a first Au junction film,
the second Au film is a second Au junction film pressed and bonded to the first Au film,
the third Au film is a first Au light reflecting film,
the fourth Au film is an Au alloy film including an AuBe alloy or an AuCr alloy, and
the fifth Au film is a second Au light reflecting film.

7. The semiconductor light-emitting device according to claim 5,
wherein a total thickness of the third Au film, the fourth Au film, and the fifth Au film is equal to or more than a total thickness of the first Au film and the second Au film.

8. The semiconductor light-emitting device according to claim 5,
wherein the thickness of the first Au film is not less than 0.075 μm and not more than 0.125 μm,
the thickness of the second Au film is not less than 0.075 μm and not more than 0.125 μm,
the thickness of the third Au film is not less than 0.01 μm and not more than 0.1 μm,
the thickness of the fourth Au film is not less than 0.05 μm and not more than 0.15 μm, and
the thickness of the fifth Au film is not less than 0.05 μm and not more than 0.15 μm.

9. The semiconductor light-emitting device according to claim 1, further comprising:
a pad electrode that is laminated on the semiconductor layer and that has a laminated structure including Au pad films each of which is made of an Au-based metal.

10. The semiconductor light-emitting device according to claim 9,
wherein a total thickness of the Au pad films exceeds the total thickness of the Au films.

11. The semiconductor light-emitting device according to claim 10,
wherein the pad electrode includes a first Au pad film, a second Au pad film, and a third Au pad film that are laminated in that order from a side of the semiconductor layer, and
the total thickness of the Au pad films is a total value of a thickness of the first Au pad film, a thickness of the second Au pad film, and a thickness of the third Au pad film.

12. The semiconductor light-emitting device according to claim 11,
wherein the thickness of the first Au pad film is not less than 0.05 μm and not more than 0.1 μm,
the thickness of the second Au pad film is not less than 0.1 μm and not more than 1 μm, and
the thickness of the third Au pad film is not less than 1 μm and not more than 3 μm.

13. The semiconductor light-emitting device according to claim 11,
wherein the pad electrode includes a Pt pad film that is interposed between the second Au pad film and the third Au pad film and that is made of a Pt-based metal.

14. The semiconductor light-emitting device according to claim 9,
wherein the pad electrode has a main body portion formed in a circular shape as viewed in plan and an arm portion linearly led out from the main body portion.

15. The semiconductor light-emitting device according to claim 14,
wherein the main body portion of the pad electrode has a width of not less than 80 μm and not more than 120 μm as viewed in plan.

16. The semiconductor light-emitting device according to claim 1, further comprising:
an insulating film that is interposed between the substrate and the semiconductor layer so as to cover the semiconductor layer and that has a contact opening by which the semiconductor layer is exposed; and
a contact electrode arranged in the contact opening so as to be electrically connected to the semiconductor layer;
wherein the metal layer is interposed between the insulating film and the substrate so as to be electrically connected to the contact electrode.

17. The semiconductor light-emitting device according to claim 16,
wherein the insulating film includes at least one of a silicon oxide film and a silicon nitride film.

18. The semiconductor light-emitting device according to claim 1, further comprising:
a translucent conductor layer interposed between the metal layer and the semiconductor layer so as to be electrically connected to the metal layer and the semiconductor layer.

19. The semiconductor light-emitting device according to claim 1,
wherein the substrate is made of a silicon substrate.

20. The semiconductor light-emitting device according to claim 1,
wherein the semiconductor layer is made of a compound semiconductor layer.
